(19) United States
(12) Patent Application Publication
(10) Pub. No.: US 2011/0036396 A1
(43) Pub. Date: Feb. 17, 2011

(54) METHOD AND APPARATUS FOR FABRICATING OPTOELECTROMECHANICAL DEVICES BY STRUCTURAL TRANSFER USING RE-USABLE SUBSTRATE

(75) Inventors: Logeeswaran Veerayah Jayaraman, Davis, CA (US); Aaron M. Katzenmeyer, Livermore, CA (US); M. Saif Islam, Davis, CA (US)

Correspondence Address: PARK, VAUGHAN, FLEMING & DOWLER LLP, 2820 FIFTH STREET, DAVIS, CA, 95618-7759, US

(73) Assignee: THE REGENTS OF THE UNIVERSITY OF CALIFORNIA, Oakland, CA (US)

(21) Appl. No.: 12/990,481

(22) PCT Filed: Apr. 30, 2009
(86) PCT No.: PCT/US09/42431

§ 371 Date: Oct. 29, 2010

(30) Foreign Application Priority Data
Apr. 30, 2008 (US) 61/049041

(51) Int. Cl. H01L 31/0352; H01L 21/50; H01L 31/18

(52) U.S. Cl. 136/255; 438/113; 438/66; 257/E21.499; 257/E31.117; 257/E31.032

(57) ABSTRACT

One embodiment of the present invention provides a process for fabricating multiple devices on a single substrate based on a structure transfer process. During operation, the process starts by forming structures of multiple devices on a first substrate. The process then bonds the structures of the multiple devices onto a second substrate. Next, the process transfers the multiple devices from the first substrate onto the second substrate by fracturing the structures of the multiple devices off the first substrate, wherein the transferred devices preserve physical orientation and material properties of the said fabricated structures.

### BACKGROUND

1. Field of the Invention

The present invention generally relates to the field of material or structure transfer and more specifically to manufacturing optoelectromechanical devices which involves the process of transferring structures from a mother substrate to a carrier substrate.

2. Related Art

Semiconductor-based electronics and photonics devices have made significant impact in communication and computing technologies. Meanwhile, rapid advances in these technologies are driving demands for monolithic integration of multifunctional materials and devices on a single substrate. These monolithically integrated materials and devices typically are associated with diverse bandgap, electrical and optical properties, and thus could offer solutions to a wide range of technological challenges, for example, in multifunctional material integration for CMOS-compatible electronics and photonics.

Significant progress in material synthesis and device integration has been demonstrated by several fabrication techniques including, epitaxial lift-off, wafer bonding, and heteroepitaxy. However, each of these fabrication techniques of combining two or more different materials on a single substrate has been limited by technological challenges. These challenges include, but are not limited to, CMOS incompatibility due to extreme physical growth conditions such as high temperature; the loss of complete starting substrates which leads to substantial cost; and the interface defects, vacancies, and traps in heteroepitaxy of mismatched materials which results in unpredictable performance degradation.

In principle, the aforementioned problems can be circumvented by fabricating high-quality crystalline structures of any given material and then harvesting the structures, while preserving the morphology to coat a target substrate/surface. The uniqueness of these structures lies in the manufacturing capabilities available to specifically tailor their electronic, photonic, thermal and mechanical properties (e.g., by varying doping concentration, sharp material junctions, and aspect ratio design etc.).

Previously, techniques have been proposed to grow structures on a high-quality starting (or “mother”) substrate and then transfer them from the mother substrate onto a low-cost carrier substrate, which often includes flexible thin carrier substrates such as metal foils and plastic sheets. Subsequently, high-quality crystalline semiconductors can be integrated on the low-cost substrate. Some transfer techniques have been proposed for plastic substrates, such as dry transfer, wet transfer, and contact printing. Unfortunately, all of these transfer techniques either do not preserve the original orientation of the array structural order on the carrier substrate or have been limited to two-dimensional (2-D) crystal film transfer.

Hence, there is a need for a three-dimensional (3D) transfer technique of high-quality crystalline inorganic semiconductors and compounds by directly transferring them from high-quality starting substrates onto lower-cost carrier substrates, while still preserving the original array order and orientation.

### SUMMARY

This invention provides methods for transferring structures from a mother (template) substrate to a receiving carrier substrate while simultaneously preserving the integrity and fidelity of the transferred structure array pattern by way of embossing, imprinting, embedding or combinations thereof, and by application of physical motions and/or physical forces that controllably exceeds the critical material stress limit of the said structure, which in turn initiates material separation by fracture-assisted material failure. These structures are formed from highly crystalline structures of different materials with diverse bandgaps and physical properties fabricated on appropriate mother substrates and transferred to form multilayered three-dimensional (3-D) stacks for multifunctional optoelectromechanical devices. This approach not only ensures the incorporation of any kind of material (with the best device characteristics) on a single substrate facilitating substrate-free device fabrication on any topology, but also applications in several areas of micro/nanoscale electronics and photonics.

One advantage of the present invention is the elimination of the need for expensive individual substrate materials for devices and circuits. This capability of fabricating substrate-less devices will offer a universal platform for material integration and enable a large number of end users to take advantage of economies-of-scale for inexpensive manufacturing of electronics and photonics, and to leverage development costs to create the technology infrastructure to make such systems powerful, inexpensive, and deployable in large numbers. The transfer technique exploits a vertical embossing and lateral fracturing method using a transfer phase change material coated on a separate carrier substrate. Ohmic contacts are formed for electrical addressing using a composite of metals and conducting polymer. The original wafer is used repeatedly for generating more devices and is minimally consumed. This heterogeneous integration technique offers devices with low fill factor contributing to lower dark current, reduced parasitic capacitance and higher efficiency of light absorption and enables high-quality, high-performance multi-material integration for large-scale application in several areas of micro/nanoscale electronics and photonics.

One embodiment of the present invention provides a process for fabricating multiple devices on a single substrate based on a structure transfer process. During operation, the process starts by forming structures of multiple devices on a first substrate. The process then bonds the structures of the multiple devices onto a second substrate. Next, the process transfers the multiple devices from the first substrate onto the second substrate by fracturing the structures of the multiple devices off the first substrate, wherein the transferred devices preserve physical orientation and material properties of the said fabricated structures.

In some embodiments, prior to bonding the structures of the multiple devices onto the second substrate, the process forms a phase-change material coating on the second substrate. The process then aligning the first substrate with the second substrate so that the structures on the first substrate are aligned over the phase-change material coating on the second substrate.

In some embodiments, the process bonds the structures of the multiple devices onto the second substrate by first pressing the second substrate against the first substrate so that at least a portion of the structures on the first substrate is imprinted and embedded into the phase-change material coating on the second substrate. The process then hardens the phase-change material coating so that the embedded portion of the structures on the first substrate is bonded with the phase-change material coating and forms anchors for the first substrate on the second substrate.

In some embodiments, prior to and during pressing the second substrate against the first substrate, the process softens the phase-change material coating to reduce the viscosity of the phase-change material coating.

In some embodiments, softening the phase-change material coating involves heating the phase-change material coating; and hardening the phase-change material coating involves cooling the phase-change material coating or treating the phase-change material coating with electromagnetic radiation.

In some embodiments, the process bonds the structures of the multiple devices onto the second substrate by softening the phase-change material coating to reduce the viscosity of the phase-change material coating. The process then presses the second substrate against the first substrate so that at least a portion of the structures on the first substrate is imprinted and embedded into the phase-change material coating on the second substrate. Note that the embedded portion of the structures on the first substrate is bonded with the phase-change material coating and forms anchors for the first substrate on the second substrate.

In some embodiments, the process softens the phase-change material coating by either heating the phase-change material coating or treating the phase-change material coating with an electromagnetic radiation.

In some embodiments, the process fractures the structures of the multiple devices off the first substrate by causing a relative motion between the first substrate and the second substrate, wherein the relative motion causes a stress-strain induced mechanical failure of the structures in the vicinity where the structures join the first substrate.

In some embodiments, the process causes the relative motion between the first substrate and the second substrate by applying a force or displacement on the bonded structure of the first substrate and the second substrate.

In some embodiments, the force can be applied to the first substrate only; the second substrate only; or both substrates.

In some embodiments, the force can be a translational force; a rotational force; or a combination of the above.

In some embodiments, the force causes shear stress in the structures; bending stress in the structures; or a combination of the above.

In some embodiments, after transferring the multiple devices from the first substrate onto the second substrate, the process deposits a filling material layer on the phase-change material coating and the transferred structures of the multiple devices, wherein the top surface of the filling material layer is below the top of the transferred structures. The process then deposits a capping layer over the filling material layer and the transferred structures, thereby encapsulating the transferred structures of the multiple devices.

In some embodiments, the filling material layer is an insulation layer.

In some embodiments, the capping layer is a conductive layer.

In some embodiments, the first substrate is a high-cost substrate.

In some embodiments, the second substrate is a low-cost substrate.

In some embodiments, the second substrate can be the final device substrate for the multiple devices or an intermediate surrogate substrate for the multiple devices.

In some embodiments, after transferring the multiple devices from the first substrate onto the second substrate, the first substrate is reused to fabricate new structures of multiple devices.

In some embodiments, the first substrate is a reused substrate.

In some embodiments, the orientation angle of the transferred structures on the second substrate can vary between 0 degrees to 90 degrees with respect to the surface of the second substrate.

In some embodiments, the phase-change material coating can be a metal-organic composite coating or a polymer coating, wherein the polymer can include thermoplastics, such as polymethylmethacrylate (PMMA), polycarbonate, polyethylene, polystyrenes, polyamide, and thermosetting plastics.

In some embodiments, the structures can include pillars of a height of at least 500 nm, and a cross-sectional dimension varying from 10 nm to 100 μm, wherein the structures are formed on a surface parallel to the first substrate.

In some embodiments, the structures can include thin walls of length L, which is at least 500 nm long, and width W, which is between 10 nm to 100 μm, wherein the thin walls are formed on a surface parallel to the first substrate.

In some embodiments, the structures can include columns with comparable dimensions between the walls length, L and widths, W1, W2, and W3.

In some embodiments, the process is repeated to form a vertical integrated stack of structures of the multiple devices on the second substrate.

In some embodiments, the structures is covered by protrusions at any arbitrary crystal orientation for either mechanical support and/or additional electrical junctions, wherein the protrusions is formed by controlling the catalyst thickness, the growth temperature, gas flow and pressure.

In some embodiments, the structures is covered by a patterned layer functioning as a mask and/or as a charge transport layer.

In some embodiments, the cross-section of the structures can include pentagon; hexagonal; octagon; circular; square; rectangular; or any other polygon shape.

In some embodiments, the structures have a central core of varying cross-sections and connected by sub-structures of blades, and fins.

In some embodiments, one or more layers in the structures are photon reflecting layers.

In some embodiments, the structures have thin walls of length, L varying from 500 nm to any conventional wafer size, the width, W1 and W2, varying from 10 nm to 100 μm formed on a surface orthogonal to the substrate. Note that the width, W1 or W2 may or may not be equal; and the height, H1 may vary between 100 nm to a conventional wafer thickness. Moreover, the walls are formed by transformative top down and/or synthetic bottom up approach.

In some embodiments, the structures are oriented by oscillation or vibration.

In some embodiments, the structures are hollow, annular, and have different cross-sections.

In some embodiments, the second substrate is capable of supporting a polymer or epoxy suitable for the extraction of the nanowires and the capability to withstand the subsequent processing conditions.

In some embodiments, the structures include distinct arrays or individual patterns on the first substrate.

In some embodiments, the phase-change material coating can include a charge transport layer.

In some embodiments, the phase-change material coating is a multilayer of one or more charge transport layers, which can include a thermoplastic, thermosetting resin, and polymeric sheet layer(s).

In some embodiments, the second substrate is coated with a polymer or an epoxy layer which is subsequently cured or allowed to cure.

In some embodiments, the polymer or epoxy layer is selectively cured, such as by applying heat to only the second substrate to facilitate structure transfer.

In some embodiments, the polymer layer is selectively cured laterally and/or vertically by controlling the focus and/or intensity of electromagnetic radiation to facilitate nanowire transfer.

In some embodiments, the epoxy resin and curing agent with a chemically-reactive excess of resin (or curing agent) is applied to the second substrate (or the original substrate) and only the curing agent (or epoxy) is applied to the original nanowire (or transfer) substrate to facilitate nanowire transfer.

In some embodiments, the structures are angularly tilted via UV curing, transfer control for directed photon trapping.

In some embodiments, the transferred structures on the second substrate are configured as multilayer optoelectromechanical device.

In some embodiments, the multiple devices include a field effect transistor (FET) device that may be re-configurable.

In some embodiments, the multiple devices include optoelectronic/photovoltaic solar cells which are formed by growing nanowire or etching pillars on the first substrate.

In some embodiments, the process grows the nanowire by patterning a metal catalyst on the first substrate to define locations where the nanowires are grown.

In some embodiments, the structures for the photovoltaic solar cell can be comprised of Silicon, Galium Nitride (GaN), Indium Phosphide (InP), Galium Phosphide (GaP) and/or Germanium (Ge).

In some embodiments, the photovoltaic solar cell can be a nanowire embedded P-I-N solar cell; or a nanowire embedded P-N solar cell.

In some embodiments, the first substrate is reused to produce additional optoelectronic/photovoltaic solar cells.

In some embodiments, the first substrate is cleaned through chemically cleaning prior to being reused.

In some embodiments, the first substrate can include a GaAs substrate; a GaP substrate; a Ge substrate; a Si substrate; or any other common substrate for multiple device fabrication.

In some embodiments, the second substrate can be made of plastic; glass; textile; or any material that supports or can be surface-treated to support the phase-change material layer.

In some embodiments, the phase-change material can be an electrically conductive material; a non-conductive/conductive polymer blend; or a conducting particle/polymer composite.

One embodiment of the present invention provides a solar power generation cell which is produced by first fabricating structures for the solar cell on a first substrate; and then transferring the structures from the first substrate to a second substrate.

In some embodiments, the structures can include a core-shell P-N or P-I-N junction, wherein the core can be a charge transport material. Note that the core-shell can be formed via a combination of bottom-up and top-down processes and the charge transport core can be formed by one of: spin-coating, dip-coating, evaporation, and sputtering.

### BRIEF DESCRIPTION OF THE FIGURES

The patent or application file contains at least one drawing executed in color. Copies of this patent or patent application publication with color drawing(s) will be provided by the Office upon request and payment of the necessary fee.

FIG. 1A illustrates the step of aligning a carrier substrate coated with a layer of phase-change material with structures anchored to a mother substrate in accordance with an embodiment of the present invention.

FIG. 1B illustrates the starting process steps for transferring structures in accordance with an embodiment of the present invention.

FIG. 1C illustrates transferred structures with the exposed fractured surfaces in accordance with an embodiment of the present invention.

FIG. 1D illustrates process steps for embedding a transferred structure in a filling material in accordance with an embodiment of the present invention.

FIG. 2A illustrates the step of aligning a carrier substrate coated with both a phase-change layer and a filling material layer with structures anchored to a mother substrate in accordance with an embodiment of the present invention.

FIG. 2B illustrates the starting process steps for transferring the structures onto the composite layers in accordance with an embodiment of the present invention.

FIG. 2C illustrates the transferred structures with the exposed fractured surfaces in accordance with an embodiment of the present invention.

FIG. 2D illustrates process steps for encapsulating the transferred structures in accordance with an embodiment of the present invention.

FIG. 3A illustrates the process of applying a translational forces on the mother substrate to transfer the structures from the mother substrate to the carrier substrate coated with the phase-change layer in accordance with an embodiment of the present invention.

FIG. 3B illustrates the process of applying a rotational force on the mother substrate to transfer the structures from the mother substrate to the carrier substrate in accordance with an embodiment of the present invention.

FIG. 3C provides a spatial coordinate system illustrating the possible directions of the applied fracturing forces in accordance with an embodiment of the present invention.

FIG. 3D illustrates temporal profiles of several exemplary fracturing forces in accordance with an embodiment of the present invention.

FIG. 4A depicts a schematic of structures in the form of slender bars or beams that are embedded in the transfer phase-change material in accordance with one embodiment of the present invention.

FIG. 4B depicts the relative motion between the mother substrate and the carrier substrate during the process of transferring the structures in accordance with one embodiment of the present invention.

FIG. 4C illustrates a system with a narrower gap separation h_{gap} along the direction of an embossing axis in accordance with one embodiment of the present invention.

FIG. 5 presents a flowchart illustrating a process for directly transferring structures into a phase-change layer by either “hardening” or “softening” the phase-change layer in accordance with one embodiment of the present invention.

FIG. 6A presents an optical image of transferred structures in the form of Si bars or micropillars in KMPR at a lower magnification in accordance with one embodiment of the present invention.

FIG. 6B presents an optical image of transferred structures in the form of Si bars or micropillars at a higher magnification in accordance with one embodiment of the present invention.

FIG. 6C presents an SEM image of the transferred structures at a lower magnification in accordance with one embodiment of the present invention.

FIG. 6D presents an SEM image of the transferred structures at a higher magnification in accordance with one embodiment of the present invention.

FIG. 7A to FIG. 7C illustrate the tilted view of the transferred Si-micropillar array in polymer polydimethylsiloxane (PDMS) spin-coated on a glass substrate at varying magnifications in accordance with one embodiment of the present invention.

FIG. 7D illustrates the mother substrate after the transfer with the remaining fractured roots of the micropillars in PDMS (the substrate can then be reused after chemical mechanical polishing (CMP)) in accordance with one embodiment of the present invention.

FIG. 8A to FIG. 8C illustrate the tilted view of the transferred Si-micropillar array in polymer polymethylmethacrylate (PMMA) spin-coated on a glass substrate at varying magnifications in accordance with one embodiment of the present invention.

FIG. 8D illustrates the mother substrate after the structure transfer with the remaining fractured roots of the micropillars in PMMA (the substrate can then be reused after chemical mechanical polishing (CMP)) in accordance with one embodiment of the present invention.

FIG. 9A illustrates an exemplary structure which is a hollow cylindrical bar in accordance with one embodiment of the present invention.

FIG. 9B illustrates another exemplary structure which is a tapered hollow cylindrical bar with the inner and outer radii varying between the two planes of intersection in accordance with one embodiment of the present invention.

FIG. 9C illustrates another exemplary structure that is a hollow rectangular bar with the inner and outer radii between the two planes of intersection in accordance with one embodiment of the present invention.

FIG. 9D illustrates another exemplary structure that is a hollow hexagonal bar with the inner and outer radii between the two planes of intersection in accordance with one embodiment of the present invention.

FIG. 9E illustrates another exemplary structure that is a solid circular bar capped with a masking layer in accordance with one embodiment of the present invention.

FIG. 9F illustrates another exemplary structure that is a hollow polygonal bar with the inner and outer radii between the two planes of intersection in accordance with one embodiment of the present invention.

FIG. 9G illustrates another exemplary structure that is a solid circular bar with the inner and outer radii between the two planes of intersection in accordance with one embodiment of the present invention.

FIG. 9H illustrates an SEM image of a bar with complex variation in the cross-sectional area in accordance with one embodiment of the present invention.

FIG. 9I illustrates another embodiment of the structure that is a bar with complex variation in the cross-sectional area on a mother substrate.

FIG. 10A illustrates another embodiment of the structure that is a thin wall on a mother substrate.

FIG. 10B illustrates another embodiment of the structure that is a complex thin wall with two orthogonal surfaces and with varying widths on a mother substrate.

FIG. 10C illustrates another embodiment of the structure that is an array of circular bars on a mother substrate.

FIG. 11A illustrates another embodiment of the structure that is a thin wall on a mother substrate with positive slopes at the base interconnected with protrusions.

FIG. 11B illustrates another embodiment of the structure that is a thin wall on a mother substrate with negative slopes at the base interconnected with protrusions.

FIG. 11C illustrates another embodiment of the structure that is a thin wall on a mother substrate with negative slopes at the base interconnected with protrusions and combined with free-standing bars.

FIG. 11D illustrates another embodiment of the structure that is an array of rectangular bars on a mother substrate obtained such that the thin walls are further etched in the orthogonal dimension to the longest width.

FIG. 12 illustrates another embodiment of the structure that is a bar with a dielectric annulus transferred onto a carrier substrate associated with a source electrode, an insulator, a gate electrode, and a drain electrode.

FIG. 13A presents an SEM image of one possible embodiment of the structure identified by protrusions and bars as illustrated in FIG. 9G or FIG. 11C.

FIG. 13B presents an SEM image of one possible embodiment of the structure identified by thin walls as illustrated in FIGS. 11A to 11C.

FIG. 13C presents an SEM image of one possible embodiment of the structure identified by thin walls and interconnected by protrusions as illustrated in FIGS. 11A to 11C.

FIG. 14A presents an SEM image of one possible embodiment of the structure identified by circular bars on a mother substrate as illustrated in FIG. 10C.

FIG. 14B presents an SEM image of one possible embodiment of the structure identified by rectangular bars on a mother substrate as illustrated in FIG. 11D.

FIG. 14C presents a close-up SEM image of one possible embodiment of the structure identified by rectangular bars on a mother substrate as illustrated in FIG. 11D.

FIG. 14D presents an SEM image of one possible embodiment of the structure identified by tapering bars on a mother substrate as partially illustrated in FIG. 9B.

FIG. 15A illustrates another embodiment of the structure with a cross-sectional area that has a “plus-form” with three distinct layers.

FIG. 15B illustrates another embodiment of the structure with a cross-sectional area that has a “star form” with three distinct layers.

FIG. 15C illustrates another embodiment of the structure with a cross-sectional area that has a “fin form” with three distinct layers.

FIG. 15D illustrates another embodiment of the structure with a cross-sectional area that has a “circular form” with three distinct layers.

FIG. 15E illustrates another embodiment of the structure with a cross-sectional area that has a “blade form” with three distinct layers.

FIG. 15F illustrates another embodiment of the structure with a cross-sectional area that has a “rectangular form” with three distinct layers.

FIG. 15G illustrates another embodiment of the structure with a cross-sectional area that has a “hexagonal form” with three distinct layers.

FIG. 15H illustrates another embodiment of the structure with a cross-sectional area that has a “rhomboid form” with three distinct layers.

FIGS. 16A-16H illustrate a mode of forming the structure, specifically a composite bar or pillar, using a top-down etching method with material deposition in accordance with one embodiment of the present invention.

FIGS. 17A-17E illustrate a mode of forming the structure, specifically a composite bar or pillar, using a bottom-up growth method or top-down etching method with material variation along the radial dimension forming a core-shell structure in accordance with one embodiment of the present invention.

FIGS. 18A-18C illustrate a mode of forming the structure, specifically a composite bar or pillar, using a bottom-up growth method with material variation along the axial dimension in accordance with one embodiment of the present invention.

FIG. 19A illustrates a mode of controlling the angle of the structure defined by the angle extended between the major axis of the structure forming a composite bar or pillar and the carrier substrate in accordance with one embodiment of the present invention.

FIG. 19B shows an optical image of the angled structures on polymer KMPR focused at the top of the structures in accordance with one embodiment of the present invention.

FIG. 19C shows an optical image of the angled structures on polymer KMPR focused at the bottom of the structure and at the top of the carrier substrate in accordance with one embodiment of the present invention.

FIG. 20A illustrates a mode of forming an optoelectromechanical device using the transferred structures, specifically composite bars or pillars with an axially varying material composition, in accordance with one embodiment of the present invention.

FIG. 20B illustrates a mode of forming an optoelectromechanical device using the transferred structures by stacking multiple individual devices in accordance with one embodiment of the present invention.

FIG. 21A presents an optical image of the device with an array of transferred vertically ordered structures on PDMS-coated glass in accordance with one embodiment of the present invention.

FIG. 21B presents an optical image of the device with an array of transferred vertically ordered structures on a curved glass surface in accordance with one embodiment of the present invention.

FIG. 22A presents the transmission properties of the transferred structure on KMPR in accordance with one embodiment of the present invention.

FIG. 22B presents the transmission properties of the transferred structure on PDMS in accordance with one embodiment of the present invention.

FIG. 22C presents the electrical properties of the transferred structure on KMPR with and without optical illumination in accordance with one embodiment of the present invention.

### DETAILED DESCRIPTION

The following description is presented to enable any person skilled in the art to make and use the embodiments, and is provided in the context of a particular application and its requirements. Various modifications to the disclosed embodiments will be readily apparent to those skilled in the art, and the general principles defined herein may be applied to other embodiments and applications without departing from the spirit and scope of the present disclosure. Thus, the present invention is not limited to the embodiments shown, but is to be accorded the widest scope consistent with the principles and features disclosed herein.

In the following discussion, note that like reference numerals refer to corresponding parts throughout the drawings. Furthermore, the same drawing numeral labeling appearing in more than one drawing refers to the same element. In addition, hereinafter, the following definitions apply:

“Mother substrate” refers to an original substrate or template that hosts the structures (later being transferred) by some form of rigid or elastic anchoring.

“Carrier substrate” refers to a surrogate or secondary substrate often flexible, lower in cost and easier to process that will host a phase-change material, which in turn will provide a secondary anchoring support for the transferred structures.

“Surrogate substrate” refers to the carrier substrate.

“Material” refers to any element in the periodic table or composites of multi-material integration.

“Transfer” refers to the process of physically relocating from one substrate, most often the mother substrate, to a receiving substrate, most often a carrier substrate.

“Structures” or “structure” refers to materials that have been shaped by any method of manufacturing on the mother substrate and are later transferred to the carrier substrate.

“Bars,” “beams,” “rods,” “pillars,” “columns,” and “frames” refer to forms of structure, typically three dimensional in geometry but with at least one major dimensional parameter for ease of transfer, wherein their cross-sections may be defined by identifiable major axes and minor axes. They also refer to any slender one-dimensional mechanical structure that has one dimension much longer (nominally by a factor>1) than the other dimensions. The structure may exhibit material and deformation properties, which can include but are not limited to elastic, inelastic, plastic, rubbery and viscoelastic. The key definitions of structure, boundary conditions and mechanism of stress-induced fracturing are consistent as described in Roark's Formula for Stress & Strain, by W. C. Young and R. G. Budynas, incorporated by reference in their entireties herein.

“Phase-change material” refers to materials in which the physical state may be manipulated between liquid and solid by at least one external physical parameter. The material may include, but is not limited to, a thermoplastic polymer, a thermoset polymer, a conducting polymer, a synthetic metal, and water.

“Filling material” refers to materials including but not limited to gases, liquids, and solids that may be disposed between the transferred structures. Filling material may include, but is not limited to, air, polymers, inorganic material, organic material, or any other conductive or insulating material.

“Conducting layer,” “charge-transport layer,” “conducting polymer,” “conducting phase-change material,” or “synthetic metal” refers to a layer that has a mechanism to conduct electrical charges from one spatial location to another.

“Coating” refers to the coverage of a surface by a material through various techniques.

“Fracture” refers to a form of failure in which the material separates in pieces due to stress at temperatures below the melting point.

“Array” refers to an ordered arrangement of structures.

“Shear” refers to a deformation in which parallel planes remain parallel but are shifted in a direction parallel to themselves. Similarly, shear force or shear stress acting in a parallel plane remains parallel but is shifted in a direction parallel to the plane.

“Bending” refers to movement that causes the formation of a curve.

“Integrity” refers to the preservation of the original quality and performance of a material.

“Fidelity” refers to the accuracy of reproduction of the original system.

“Embedding” refers to containing or submerging a structure inside another material, typically the phase-change material.

“Imprinting” refers to stamping by application of pressure, or to a significant depth inside the host material.

“Embossing” refers to stamping by application of pressure, or to a shallower depth compared to imprinting inside the host material.

“Physical motions” refers to displacements or location change.

“Physical forces” refers to the physical influence that produces a change in a physical quantity.

“Anchor,” “anchoring” refer to mechanically restricting motions.

“Dynamic” refers to a physical quantity varying with time.

“Static” refers to a physical quantity remaining constant for a period of time.

“Impulse” refers to a physical quantity with a huge magnitude being applied for a very short duration of time.

“Critical material stress limit,” and “ultimate strength” refer to the limits of stress that a material under tensile, compressive, shear, bending and torsional load can sustain prior to fracture.

“Fracture-assisted material failure” refers to material separation due to fracture when the stress exceeds the material ultimate strength. The signature of fracture is identifiable in the microscopic sense via slip lines which, in turn, represent the intersection of the surface by planes on which shear stress has produced plastic slip.

“Aspect ratio” refers to the ratio of the dimension on the central polar axis to the dimension on the major axis on the plane of the cross-section passing through the centroid, typically the height to width ratio or the length to radius ratio.

“Major axis” refers to the larger line of axis passing through the centroid on the plane of the cross-section of the structure.

“Minor axis” refers to the smaller line of axis passing through the centroid on the plane of the cross-section of the structure.

“Frames” refers to beams in two- or three-dimensional space.

“P-N” refers to p-doped (P) and n-doped (N) junction diode.

“P-I-N” refers to p-doped (P), intrinsic (I), n-doped (N) junction diode.

Embodiments of the present invention provide techniques for transferring structures from a mother (starting) substrate to a carrier (receiving) substrate while simultaneously preserving the properties of the transferred structures by way of embossing, imprinting, embedding or combinations of the above, and by application of physical motions and/or physical forces that controllably exceed the critical material stress limit of said structure, which in turn initiates material separation by fracture-assisted material failure. These structures may be formed from highly crystalline structures of different materials with diverse bandgaps and physical properties fabricated on appropriate mother substrates and transferred to form multilayered three-dimensional (3-D) stacks for multifunctional optoelectromechanical devices.

Embodiments of the present invention not only facilitate incorporating any kind of material (with the best device characteristics) on a single substrate to facilitate substrate-free device fabrications on any topology, but also facilitate reusing a mother substrate for continuous production of new devices. The transfer technique includes a vertical embossing process and a lateral fracturing process using a phase-change material layer coated on a separate carrier substrate. Ohmic contacts can be formed on the transferred structures for electrical connections by using a composite of metals and conducting polymer. This heterogeneous integration technique provides devices with low fill factor contributing to lower dark current, reduced parasitic capacitance and higher efficiency of light absorption. This technique also enables high-quality, high-performance multi-material integration for large-scale applications in several areas of micro/nanoscale electronics and photonics.

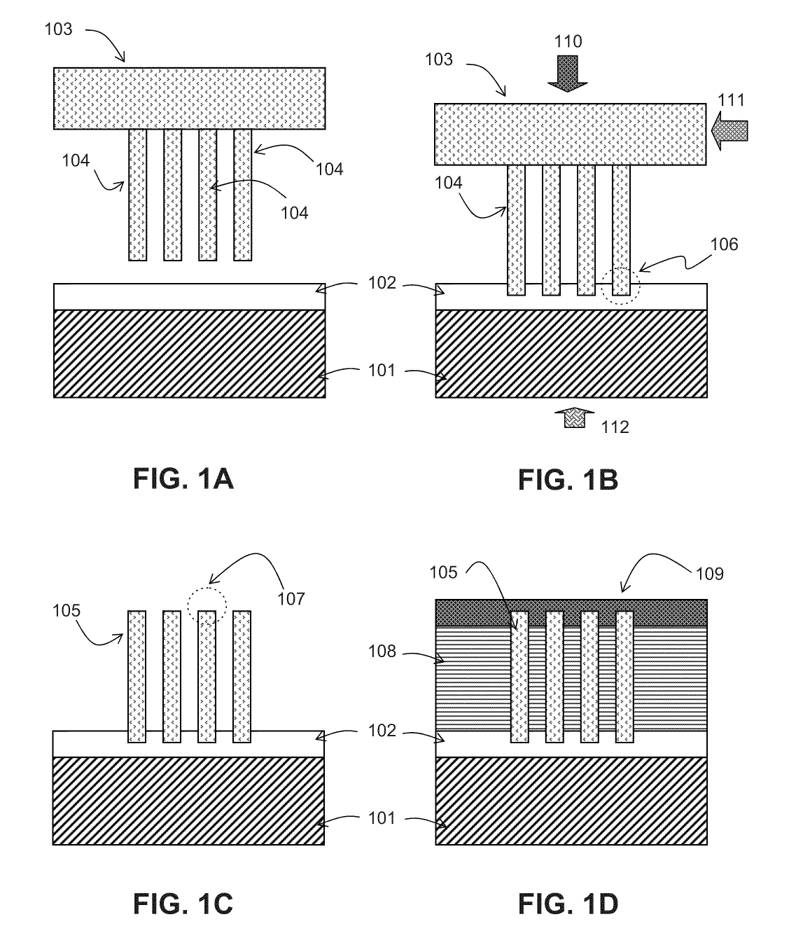

FIG. 1 illustrates a process of transferring structures 104 from a mother substrate 103 to a carrier substrate 101 coated with a layer of phase-change material 102 in accordance with an embodiment of the present invention. Phase-change material 102 may be formed or comprised of synthetic metals, conducting polymers, or nanoparticle-enhanced conducting polymer, among others.

More specifically, FIG. 1A illustrates the step of aligning carrier substrate 101 coated with a layer of phase-change material 102 (“phase-change layer 102” hereinafter) with structures 104 anchored to mother substrate 103 in accordance with an embodiment of the present invention. As seen in FIG. 1A, structure 104 is now directly facing the top surface of phase-change material layer 102.

FIG. 1B illustrates the starting process steps for transferring structures 104 in accordance with an embodiment of the present invention. In one embodiment, carrier substrate 101 is thermally heated using a heat source 112 to lower the viscosity of phase-change layer 102. Note that, in addition to thermal heating, other forms of treatment which can reduce the viscosity of phase-change layer 102 may be used, for example, by using a UV radiation treatment. Next, mother substrate 103 is brought into contact with carrier substrate 101 so that structures 104 are embossed into phase-change layer 102 by a combination of physical motions and/or physical forces 110 (which is typically a vertical translational motion and force). The embedded portions of structures 104, referred to as structures 106, now act as an anchor to provide a rigid support of mother substrate 103. Note that during the process of embossing the phase-change layer 102 is kept at an elevated temperature through heated. At the end of the embossing process, a large gap is typically formed between mother substrate 103 and phase-change layer 102.

Next, carrier substrate 101 is cooled to increase the viscosity of the phase-change layer 102, thereby physically hardening it. Lateral physical motions and/or physical forces 111 are then applied to cause material failure to occur in structures 104, thus effectively transferring structures 104 from mother substrate 103 to carrier substrate 101.

FIG. 1C illustrates transferred structures 105 with the exposed fractured surfaces 107 in accordance with an embodiment of the present invention. Note that structures 104 broke off from mother substrate 103 at the interface between structures 104 and mother substrate 103. The structures transferred onto carrier substrate 101 are referred to as structures 105. Mother substrate 103 can now be reused to grow new structures, and then repeat another cycle of process. In some embodiments, to make mother substrate 103 reusable, the surface of mother substrate 103 can be either chemically etched or planarized using chemical mechanical polishing (CMP) to remove the residuals of structures 104.

FIG. 1D illustrates process steps for embedding transferred structure 105 in a filling material 108 in accordance with an embodiment of the present invention. Filling material 108 can be either conductive or insulating (either electrically or thermally). Note that in this embodiment, the top portion of structures 105 is above the top surface of filling material 108 and exposed. On top of filling material 108, a top (e.g., a charge transport) layer 109 is then deposited over filling material 108 and transferred structures 105. In one embodiment, if the initial phase-change layer 102 is electrically conductive, then phase-change layer 102, insulating filling material 108, transferred structures 105, and top electrically conducting (charge transport) layer 109 form an electronic device.

In some embodiments, structures 105 may be designed into a device for electrostatic charge accumulation or as a capacitive device commonly used in transistors and energy storage devices, or as an active vibrating element of a microelectromechanical device. Moreover, structures 105 may be designed to control and manipulate tensile or compressive stress distribution within embedded structures 105 in FIG. 1D.

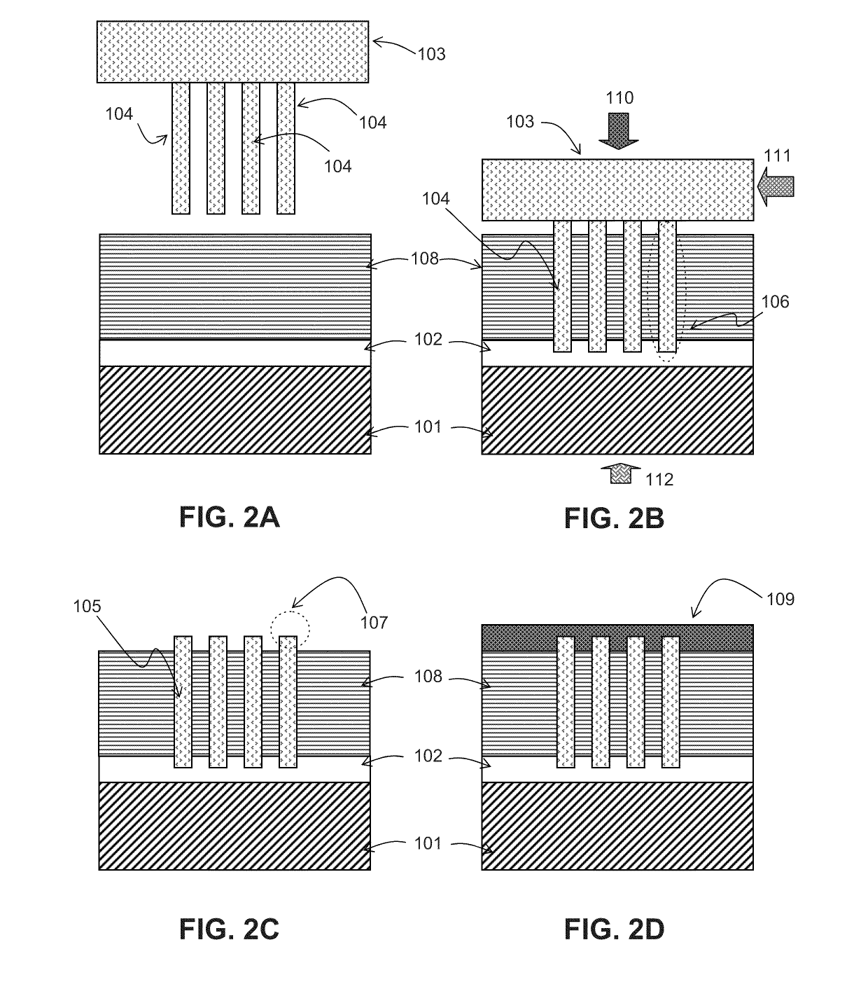

FIG. 2 illustrates a process of transferring structures 104 from a mother substrate 103 to a carrier substrate 101 coated with both a phase-change layer 102 and a filling material 108 in accordance with an embodiment of the present invention.

More specifically, FIG. 2A illustrates the step of aligning carrier substrate 101, which is coated with both a phase-change layer 102 and a filling material layer 108, with structures 104 anchored to mother substrate 103 in accordance with an embodiment of the present invention. As seen in FIG. 1A, structures 104 are now directly facing the top surface of filling material layer 108.

FIG. 2B illustrates the starting process steps for transferring structures 104 onto the composite layers of 102 and 108 in accordance with an embodiment of the present invention. In one embodiment, carrier substrate 101 is thermally heated by using a heat source 112 to lower the viscosity of either filling material layer 108 or the composite layers 102 and 108. Note that in addition to thermal heating, other types of treatment which can reduce the viscosity of filling material layer 108 or the composite layers 102 and 108 may be used, for example by using a UV radiation treatment. Next, mother substrate 103 is brought into contact with carrier substrate 101 so that structures 104 are embossed into filling material layer 108 and/or phase-change material 102 by a combination of physical motions and/or physical forces 110 (which is typically a vertical translational motion and force). The embedded portion of structures 104, referred to as structures 106, now act as an anchor to provide a rigid support of mother substrate 103. Note that during the embossing step filling material layer 108 or the composite layers 102 and 108 continue to be heated to keep the viscosity low. At the end of embossing process, a small gap is typically formed between mother substrate 103 and filling material layer 108.

Next, carrier substrate 101 is cooled to increase the viscosity of filling material layer 108 or the composite layers 102 and 108, thereby physically hardening these layers. Lateral physical motions and/or physical forces 111 are then applied to cause material failure to occur in structures 104, thus effectively transferring structures 104 from mother substrate 103 to carrier substrate 101.

FIG. 2C illustrates transferred structure 105 with the exposed fractured surfaces 107 in accordance with an embodiment of the present invention. Note that structures 104 broke off from mother substrate 103 at the interface between structures 104 and mother substrate 103. Mother substrate 103 can now be reused to grow new structures, and then repeat another cycle of process. In some embodiments, to make mother substrate 103 reusable, the surface of mother substrate 103 can be either chemically etched or planarized using CMP to remove the residuals of structures 104.

FIG. 2D illustrates process steps for encapsulating transferred structures 105 in accordance with an embodiment of the present invention. Note that filling material layer 108 can be conductive or insulating (either electrically or thermally). In this embodiment, the very end portion of structures 105 is above filling material layer 108 and exposed. On top of filling material layer 108, a top (charge transport) layer 109 is then deposited over filling material layer 108 and transferred structures 105. In one embodiment, if the initial phase-change layer 102 is electrically conductive, then phase-change layer 102, insulating filling material layer 108, transferred structures 105, and top electrically conducting (charge transport) layer 109 form an electronic device. This multi-layer structure is substantially identical to the final device structure illustrated in FIG. 1D.

In some embodiments, structures 105 may be designed into a device for electrostatic charge accumulation or as a capacitive device commonly used in transistors or energy storage devices. Moreover, structures 105 may be designed to control and manipulate tensile or compressive stress distribution within embedded structures 105 in FIG. 2D.

One object of the present invention is to transfer structures 104 from mother substrate 103 to carrier substrate 101 by using the sequential steps of heating, embossing, cooling and fracturing. A successful fracturing is facilitated by applying a proper fracturing force.

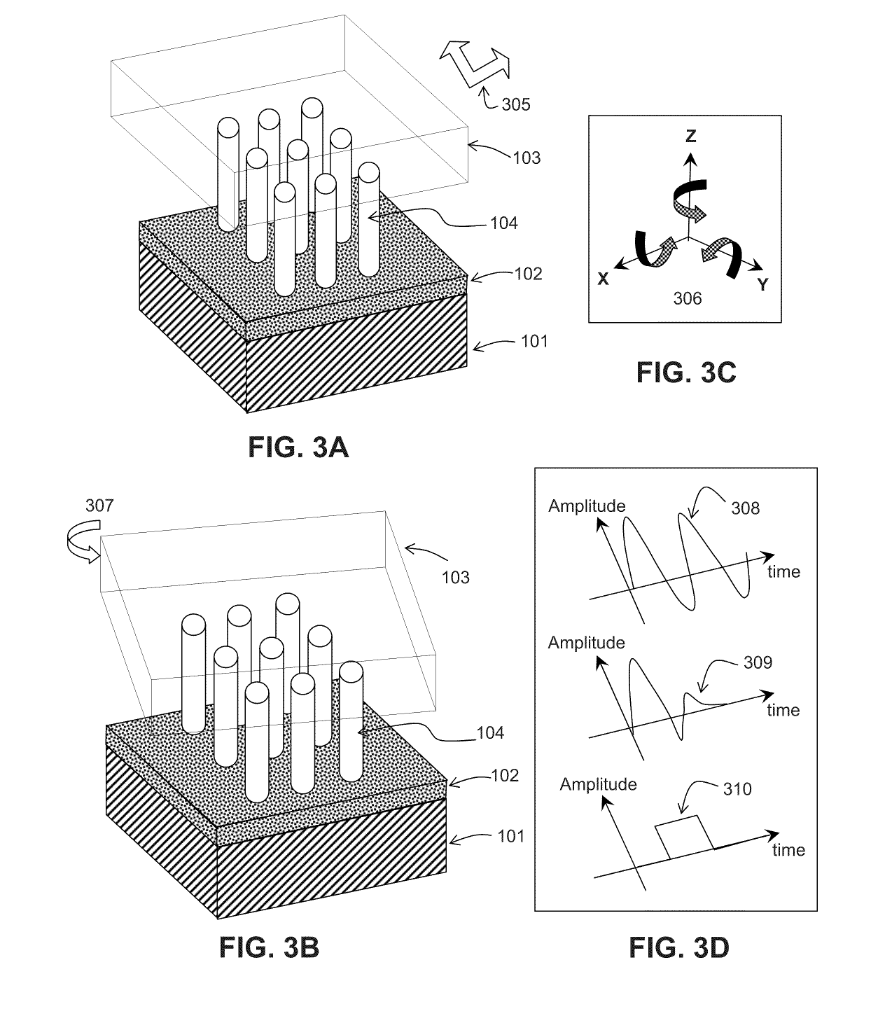

FIG. 3A illustrates the process of applying a translational fracturing force 305 to mother substrate 103 to transfer structures 104 from mother substrate 103 to carrier substrate 101 coated with phase-change layer 102 in accordance with an embodiment of the present invention. Note that fracturing force 305 is typically applied in the plane of substrate 103 but can be applied in an arbitrary direction in the substrate plane. In some embodiments, translational fracturing force 305 may also be applied to carrier substrate 101 relative to mother substrate 103.

Structure transfer from a mother substrate to a carrier substrate may also be achieved by applying rotational forces. FIG. 3B illustrates the process of applying a rotational force 307 to mother substrate 103 to transfer structures 104 from mother substrate 103 to carrier substrate 101 in accordance with an embodiment of the present invention. Note that rotational fracturing force 307 is typically applied in the plane of mother substrate 103. In some embodiments, rotational fracturing force 307 may also be applied to carrier substrate 101 relative to mother substrate 103.

In practice, the rotational fracturing forces can comprise more than one rotational axis. FIG. 3C provides a spatial coordinate system 306 for illustrating the possible directions of applied fracturing forces 111 in FIG. 2B in accordance with an embodiment of the present invention. Generally, the directions of fracturing forces 111 may be purely translational, purely rotational, or any combination thereof.

FIG. 3D illustrates temporal profiles of several exemplary fracturing forces 111 in FIG. 2B in accordance with an embodiment of the present invention. More specifically, FIG. 3D presents amplitude vs. time profiles of three types of fracturing forces 111: sinusoid 308, impulse 309, and quasi-static 310.

In the present invention, to successfully separate the structures (for example, nanowires/nanopillars) from the mother substrate, the fracture strengths of these structures under a general applied load (which can include bending, compression, tension, shear and torsion) need to be understood. Specifically, the material fracturing behavior dictates the mechanical separation process. Both static and dynamic experimental techniques have been applied to quantify the material properties such as Young's modulus and maximum bending stress based on Euler elastic beam theory. In one experiment, a magnetomotive dynamic measurement of mechanical properties of epitaxially connected nanowire beams showed that the bending modulus is roughly ˜170 GPa. In another experiment using bridged silicon (Si) nanowires, and by applying a static force with an atomic force microscopy (AFM) tip, the measured bending strength of nanowires epitaxially connected to a single crystal surface was found to be the average critical bending stress of ˜500 MPa, which is about ˜0.3% of the Young's modulus.

Other studies have reported much higher bending stress. In one model, the maximum bending stress is correlated with length, diameter, and Young's modulus of nanowires using the following expression (assuming a fix-free cantilever boundary condition):

$${σ}_{z , max} = \frac{3}{2} \frac{d}{{l}^{2}} E ( Δ x ) , \qquad ( 1 )$$

where d, E, Δx and l are the structural nanowire diameter, Young's modulus, bending displacement, and the structural nanowire length, respectively. The maximum tensile stress theoretically occurs at the location where nanopillar/nanowire meets with the substrate surface. Using an AFM inside a scanning electron microscopy (SEM) to estimate the average fracture strength, it is found to be ˜10 GPa, ˜6% of the Young's modulus. Based on the above Si nanowire data, it can be seen that the fracture strength of most nanoscale semiconductors will be significantly lower than their respective Young's modulus. For Si, a shear strength is estimated to be ˜5-7 GPa. Knowledge of the fracture strengths of nanopillars fabricated in Ge, InP, GaAs, CdSe and other materials are also highly desirable.

Note that separating structures through bending fracture either by point load or uniformly distributed load can require a significant amount of beam deflection, Δx. This required amount of beam deflection may be reduced by embedding a greater portion of the nanopillar structures in the phase-change layer. In some embodiments, the phase-change layer thickness is chosen to rigidly encapsulate about ⅔ of the nanopillar structures, thus facilitating separation of the structures from the substrate by shearing rather than bending stress. In general, any single crystalline inorganic semiconductor structure can be fractured during the structure transfer process in the polymer matrix by any combination of bending, shear, tensile, compressive or torsional force. Note that all applied physical forces 305 and 307 in practice may exceed the commonly published critical fracture or yield stress values for most materials of interest.

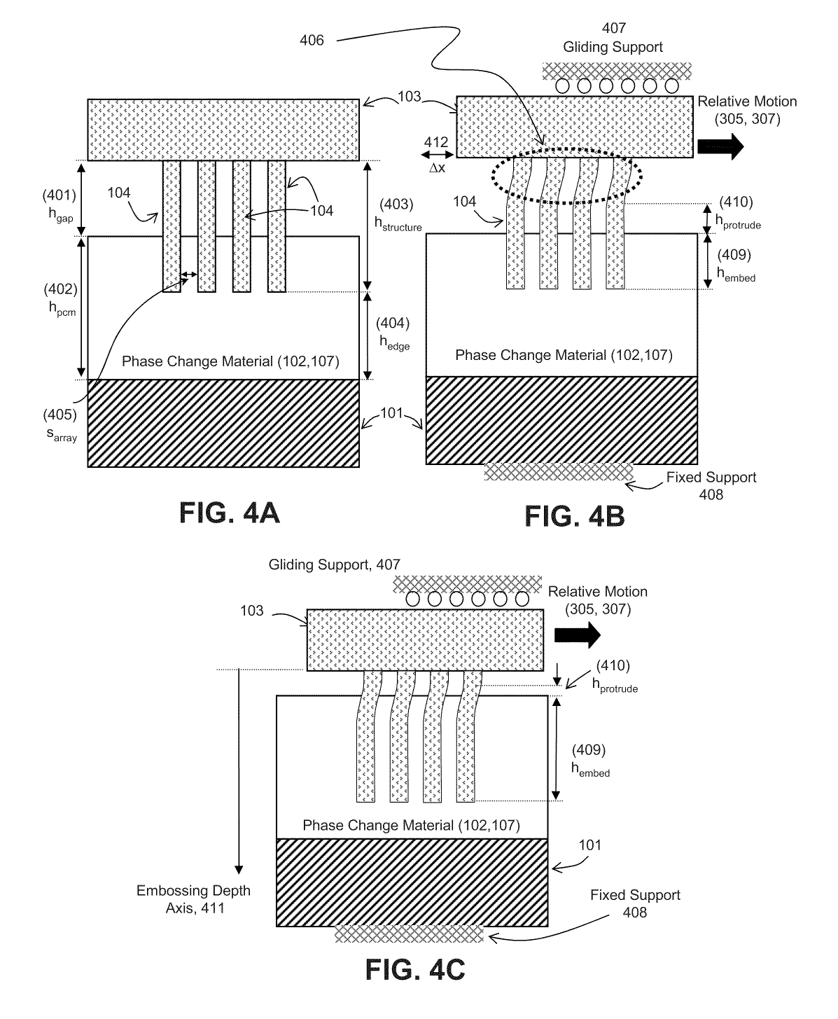

FIG. 4 illustrates parameters associated with the mechanical fracturing and the mechanics of the transfer process in accordance with one embodiment of the present invention.

More specifically, FIG. 4A depicts a schematic of structures 104 in the form of slender bars or beams that are embedded in the transfer phase-change material in accordance with one embodiment of the present invention. Without loss of generality, structures 104 are depicted as a set of beams with height (h_{structure}) 403. Set of beams 104 are anchored to mother substrate 103 in an ordered array with spacing (s_{array}) 405 and to a carrier substrate 101 coated with a phase-change layer 102 with thickness (h_{pcm}) 402. Structures 104 are embossed and embedded into phase-change layer 102, wherein the tip of structures 104 has a distance (h_{edge}) 404 from carrier substrate 101. Furthermore, h_{gap} 401 represents the gap between the root of structures 104 and the free-surface of phase-change layer 102.

FIG. 4B depicts the relative motion between mother substrate 103 and carrier substrate 101 during the process of transferring structures 104 in accordance with one embodiment of the present invention. To successfully transfer structures 104 from mother substrate 103 to carrier substrate 101, mother substrate 103 and carrier substrate 101 move in opposing directions under an applied fracturing force, which can include but is not limited to shear, bending, tensile, compression, and torsion fracturing or combinations of the above. As seen in FIG. 4B, a region of critical stress 406 is shown in which structures 104 experiences the greatest displacement. Region of critical stress 406 may be designed to fail mechanically through fracture under applied fracturing forces (305 and 307) by carefully choosing design parameters, specifically, h_{protrude} 410 and h_{embed} 409, as well as material properties of structures 104.

The boundary conditions for such a mechanical system may include a gliding support 407 for mother substrate 103 and a fixed support 408 for carrier substrate 101. Note that these boundary conditions which are established before, during and after the transfer process need not be limited to commonly known mechanical boundary conditions. In one embodiment, the mechanical boundary conditions may be substituted with electrostatic clamping to achieve the same function of restricting the freedom of motion. Although the boundary conditions illustrated in FIG. 4B include fixed support 408 and gliding support 407, any variation to this specific embodiment that achieves the same function of motion restriction can be used in place of the specific embodiment illustrated in FIG. 4B.

In comparison to FIG. 4B, FIG. 4C illustrates a similar system with a narrower gap separation h_{gap} 401 along the direction of embossing axis 411 in accordance with one embodiment of the present invention. Typically, shearing fractures of bar structures 104 are more effective when gap separation h_{gap} 401 is smaller, whereas bending fractures of bar structures 104 are more effective when gap separation h_{gap} 401 is greater.

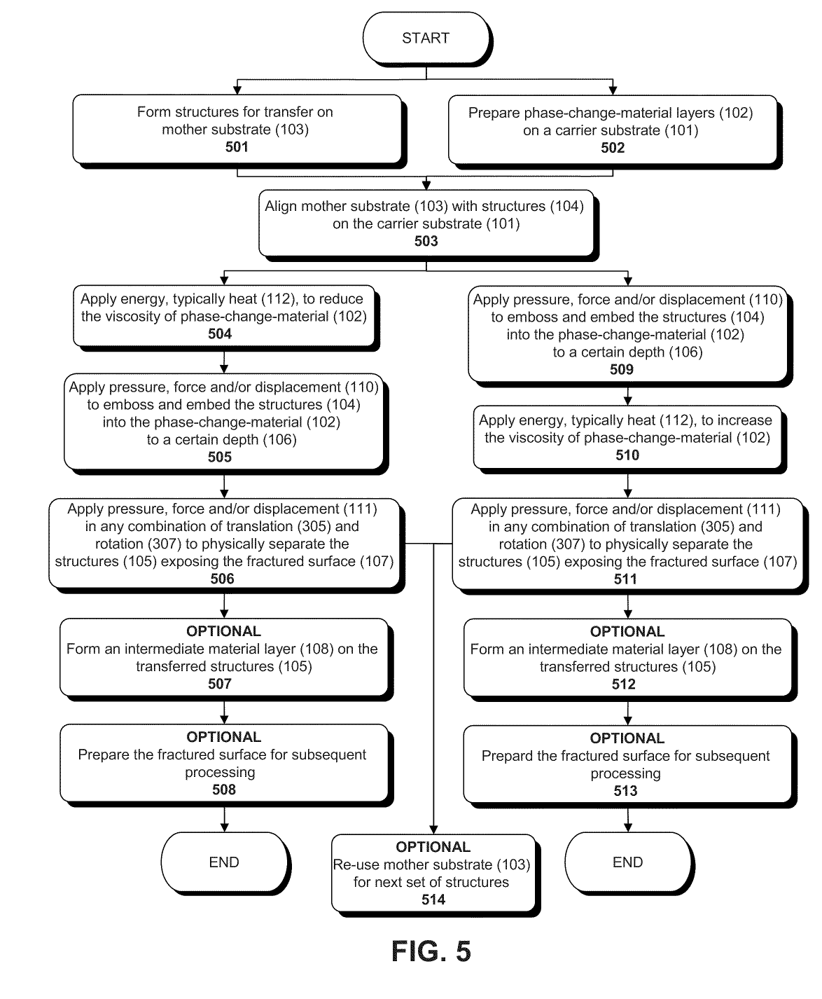

FIG. 5 presents a flowchart illustrating a process for directly transferring structures into a phase-change layer by either “hardening” or “softening” the phase-change layer in accordance with one embodiment of the present invention. In this embodiment, “hardening” refers to a process in which the actual structures 104 are embossed into a phase-change layer 102 that is kept at room temperature; while “softening” refers to a process in which the actual structures 104 are embossed into a phase-change layer 102 that is kept at an elevated temperature.

Note that the process in FIG. 5 comprises two process paths: a hardening path (the right-hand branch in FIG. 5) and a softening path (the left-hand branch in FIG. 5). The process path for “hardening” begins by forming structures on a mother substrate (step 501) and separately preparing a phase-change material layer on a carrier substrate (step 502). The two substrates are then aligned such that the structures on the mother substrate face the phase-change layer on the carrier substrate (step 503). Next, a vertical force (with respect to the substrate plane) is applied to emboss and embed the structures into the phase-change layer to a predetermined depth (step 509). The system is then heated to harden the phase-change material through a solvent evaporation process that increases the viscosity with cross-linking mechanism (step 510). Next, a lateral force is applied on either the mother substrate or the carrier substrate to cause mechanical fracture and thus achieve structural transfer (step 511). Note that this step exposes the fractured surfaces. After the structures are transferred from the mother substrate to the carrier substrate, further processing may be performed to coat intermediate layers on the transferred structures (step 512) or to prepare the fractured surface for further processing (step 513). Note that either or both steps 512 and 513 may be optional.

The process path for “softening” begins by forming structures on a mother substrate (step 501) and separately preparing a phase-change layer on a carrier substrate (step 502). The two substrates are then aligned such that the structures on the mother substrate face the phase-change material layer on the carrier substrate (step 503). The system is then heated to soften the phase-change layer by decreasing its viscosity (step 504). Next, a vertical force (with respect to the substrate plane) is applied to emboss and embed the structures into the phase-change material to a predetermined depth (step 505). Next, a lateral force is applied on either the mother substrate or the carrier substrate to cause mechanical fracture and thus achieve structural transfer (step 506). Note that this step exposes the fractured surfaces. After the structures are transferred from the mother substrate to the carrier substrate, further processing may be performed to coat intermediate layers on the transferred structures (step 507) or prepare the fractured surface for further processing (step 508). Note that either or both steps 507 and 508 may be optional.

In some embodiments, after the structures are transferred from the mother substrate to the carrier substrate at step 506 or step 511, the mother substrate can then be reused for preparing new structures (step 514).

It is yet another objective of the present invention to provide embodiments of structure and array with geometrical configuration that may be varied in accordance with the body of knowledge known as Group Theory.

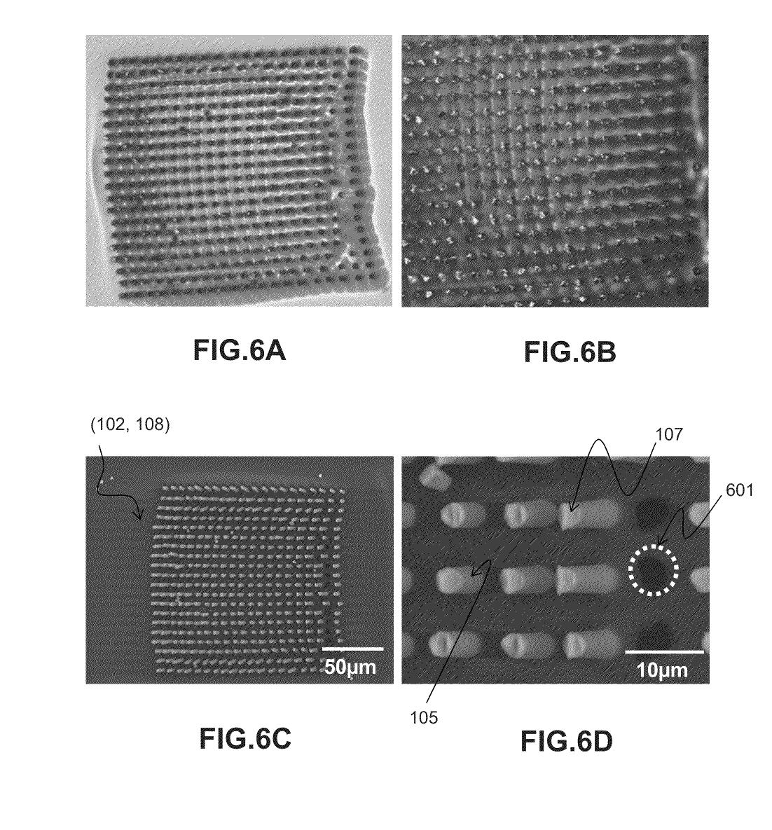

FIG. 6A and FIG. 6B present optical images of transferred structures in the form of Si bars or micropillars at different magnifications (lower in FIG. 6A and higher in FIG. 6B). In this embodiment, the mother substrate is first cleaved to a smaller die of size ˜5 mm by 5 mm. The phase-change material is a negative epoxy polymer (KMPR) that is separately spin-coated onto individual glass substrates of size ˜1″ by 1″. The polymer layers have different pre- and post-embossing bake recipes before transferring the micropillars via fracturing. The optical specular reflections seen in FIG. 6A and FIG. 6B are from the fractured crystalline surfaces.

FIG. 6C and FIG. 6D present the SEM images of the transferred structures 105 with different magnifications (lower in FIG. 6C and higher in FIG. 6D). The embossing of Si micropillars onto KMPR spin-coated glass substrate may be achieved by using a force load of ˜10 mN on an array pillar contact area of ˜5.7×10⁻⁹ m² for an applied pressure of ˜1.8 MPa. The depth of embedding “h_{embed}” is ˜10 μm. After the two substrates have been baked at 100° C. for 5 mins, a lateral force using a micropositioner is applied to induce fracture and separation and thus transfer the micropillars to the carrier substrate.

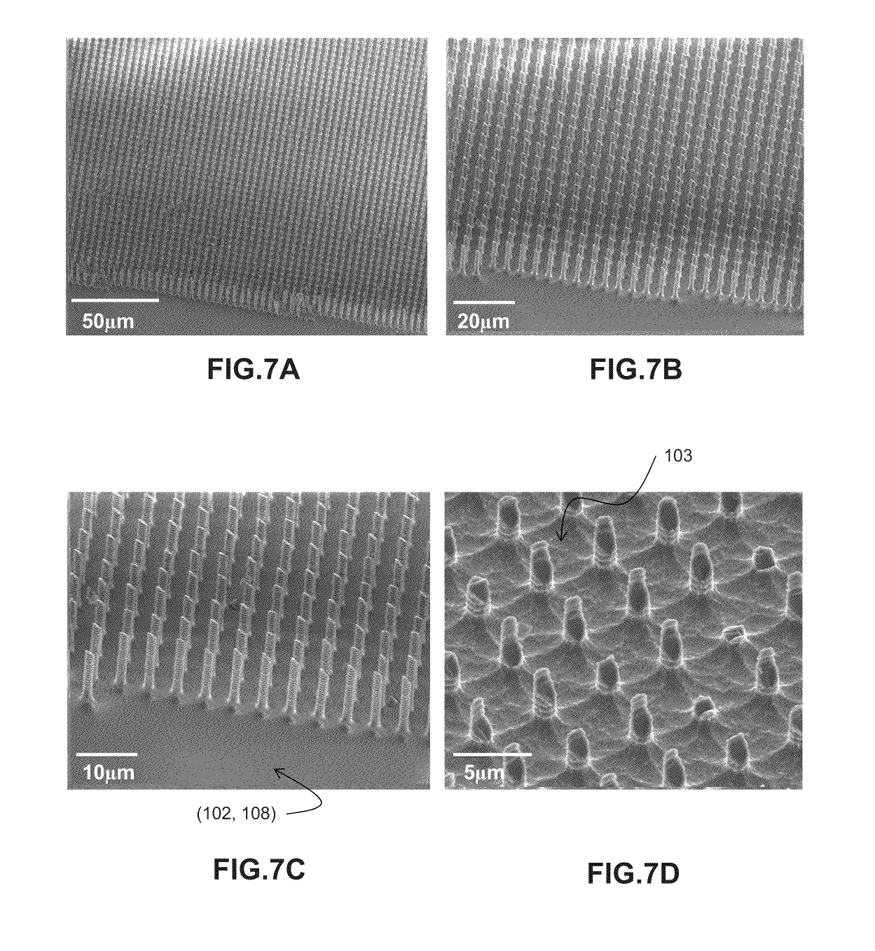

FIGS. 7A-7D present a similar embossing-fracturing process sequence performed on a glass substrate which is spin-coated with a polymer polydimethylsiloxane (PDMS), with an exception that the pre-embossing curing was done for 6 hours at room temperature. The actual transferred structures in the form of bars or micropillars are shown with different magnifications. The mother substrate was first cleaved to a smaller die of size ˜5 mm by 5 mm. The phase-change material was a polymer PDMS that was separately spin-coated onto individual glass substrates of size ˜1″ by 1″. FIGS. 7A to 7C present the tilted SEM images of the transferred micropillar arrays with varying image magnifications (in an increasing order). These images clearly demonstrate the preservation of the original array pattern fidelity over a large printed area. An embossing force of ˜10 mN was applied on an array pillar contact area of ˜9.2×10⁻⁷ m² for an applied pressure of ˜10.8 kPa. The depth of embedding was ˜5 μm. After the lateral fractured transfer, some remnant roots of the micropillars on the mother substrate are shown in FIG. 7D. To make this mother substrate reusable again, the surface non-planarity can be either chemically etched away or planarized using chemical mechanical polishing (CMP).

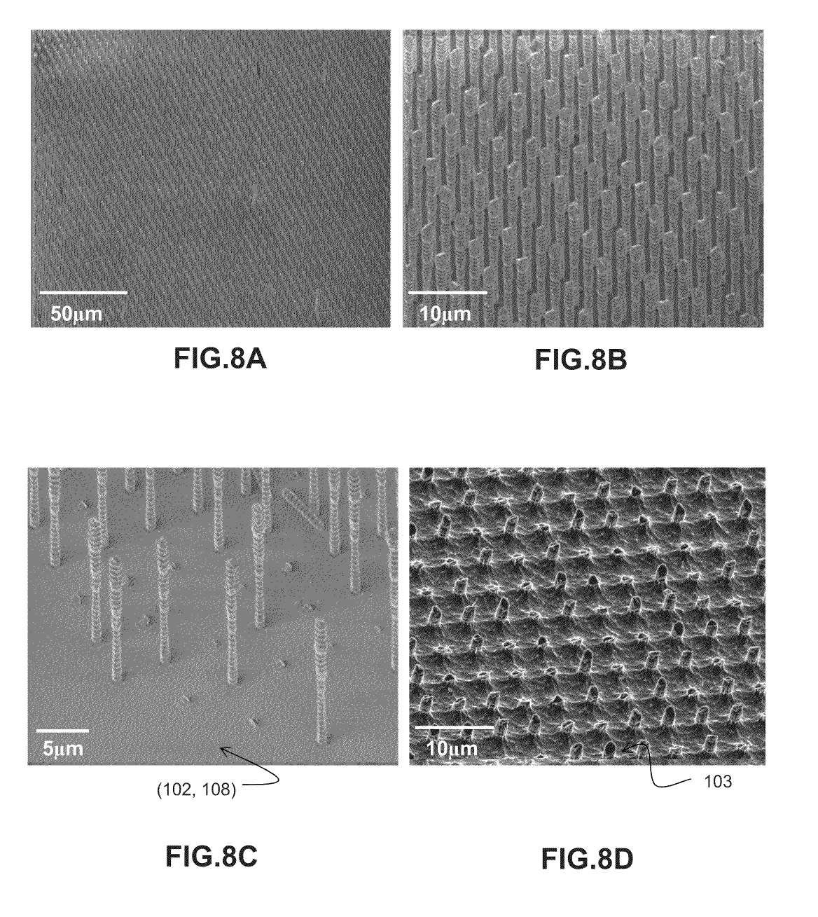

FIGS. 8A-8D present another embossing-fracturing process sequence performed on a glass substrate which is spin-coated with PMMA. For the transfer onto a thermoplastic polymer PMMA, the carrier substrate was first heated to a temperature of 220° C. The micropillar die was then placed on the PMMA surface while simultaneously applying an embossing force of ˜100 mN on a pillar array contact area of ˜3.7×10⁻⁷ m² for an applied pressure of ˜0.27 MPa. The “bonded” substrates were allowed to cool to room temperature prior to the lateral fracturing. The depth of embedding was ˜6 μm and the resulting transfer images are shown in FIG. 8As to 8C in an order of increasing magnification. Similar to the PDMS transfer, remnant roots of the micropillars are clearly visible on the mother substrate as seen in FIG. 8D. In one embodiment, the substrate can then be reused after performing chemical mechanical polishing (CMP) on the mother substrate.

Note that both the KMPR and PDMS phase-change layers have the advantage of room temperature embossing while PMMA-based phase-change layer needs a heated substrate at 140° C.-220° C. Some exemplary conditions for polymer transfer layer preparations are detailed in Table 1 for all three polymers.

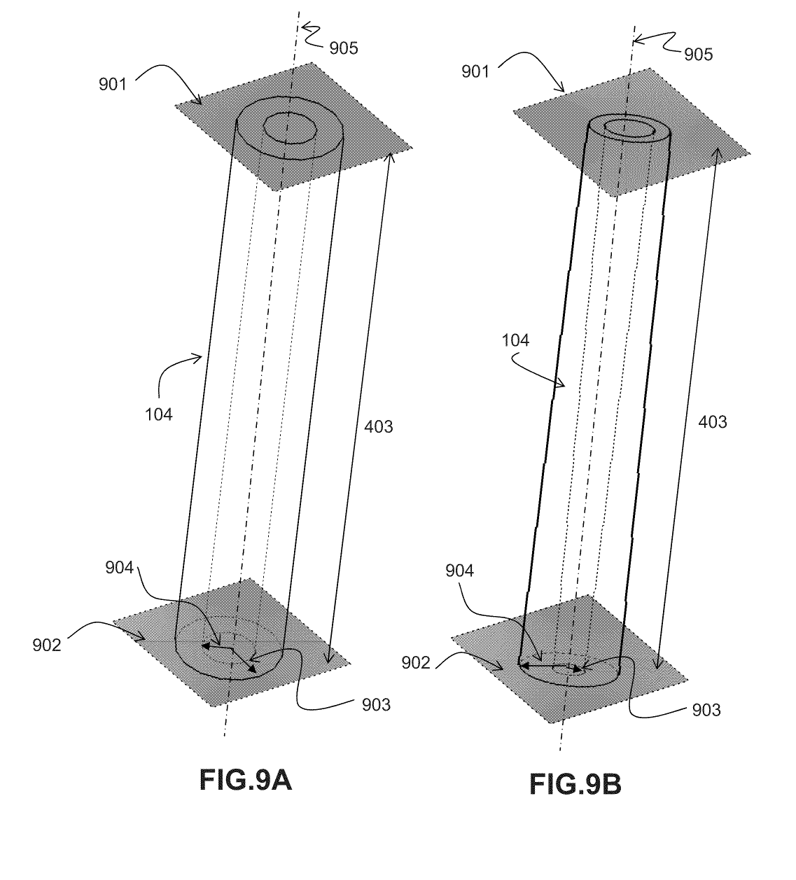

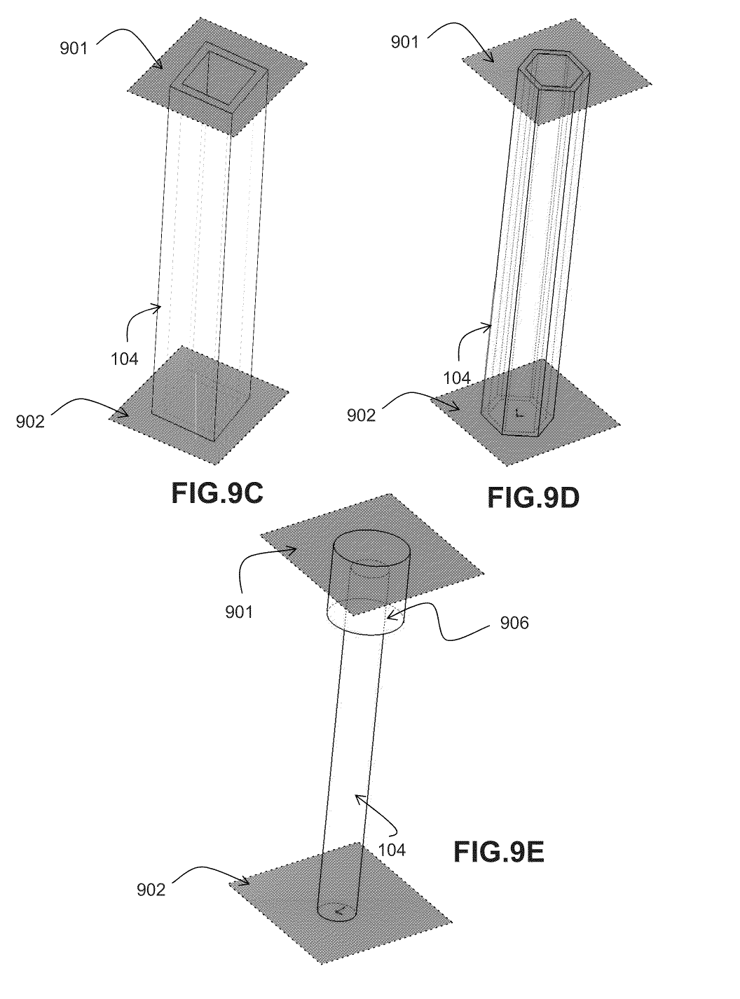

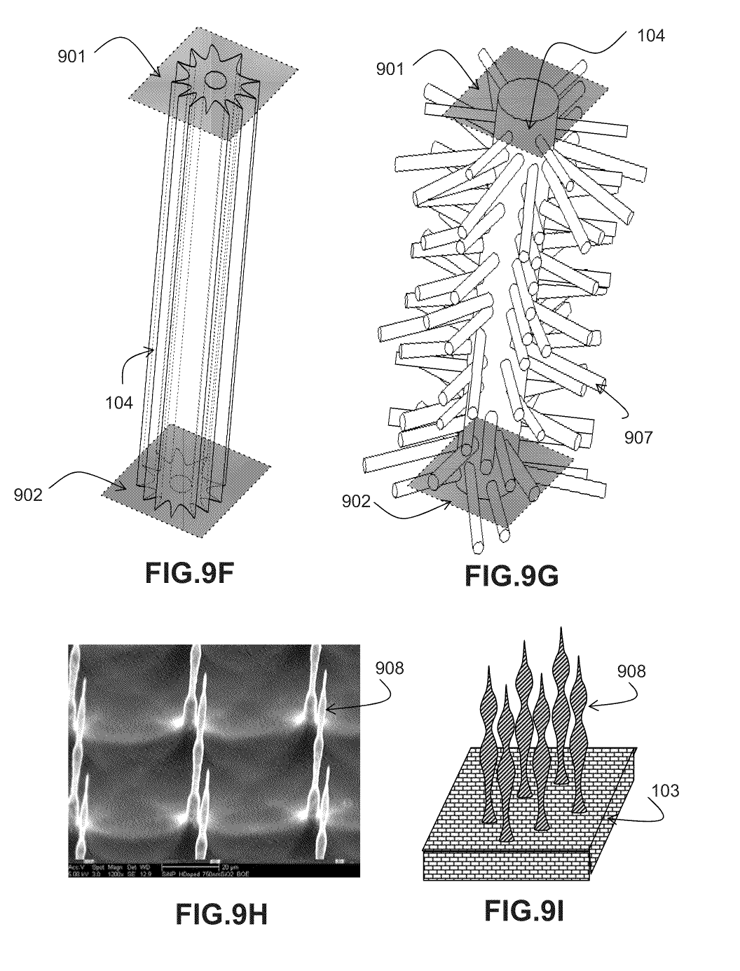

FIG. 9 illustrates exemplary structures 104 in accordance with one embodiment of the present invention. More specifically, FIG. 9A illustrates a hollow cylindrical bar 104 associated with a certain dimension 403, defined by artificially constructed planes of intersection 901 and 902 with the centroid of the cross-sectional area of the bar. The top plane 901 is typically facing away from the mother substrate while the bottom plane 902 is facing the mother substrate. The cross-sectional area is defined by the inner and outer radius 904 and 903, which need not be parallel.

TABLE 1
Parameters for polymer layer preparation prior to embossing & transfer

| | | | Embossing | |
|---|---|---|---|---|
| Process Steps | Thickness | Pre-Embossing | Temperature | Post-Embossing |
| KMPR | ~8-10 μm | 30 sec @ 95° C. | 30° C. | 5 mins @ 100° C. |
| PDMS | ~30-50 μm | 6 hr @ 30° C. | 30° C. | 15 mins @ 80° C. |
| PMMA | ~6-10 μm | 60 sec @ 95° C. | 140° C.-220° C. | 2 mins @ 220° C. |

FIG. 9B illustrates another embodiment of the structure 104 that is a tapered hollow cylindrical bar with the inner and outer radii 904 and 903 varying between the two planes of intersection 901 and 902. Their variation is in opposition to each other with respect to the bar's height 403. Such variations may be useful for specific device performance or ease of fabrication.

FIG. 9C illustrates another embodiment of the structure 104 that is a hollow rectangular bar with the inner and outer radii 904 and 903 between the two planes of intersection 901 and 902.

FIG. 9D illustrates another embodiment of the structure 104 that is a hollow hexagonal bar with the inner and outer radii 904 and 903 between the two planes of intersection 901 and 902.

FIG. 9E illustrates another embodiment of the structure 104 that is a solid circular bar capped with a masking layer 905. This layer may be a metal catalyst or any commonly used masking layer for processing the bar 104. The metal cap 906 may be deposited by selective angle evaporation.

FIG. 9F illustrates another embodiment of the structure 104 that is a hollow polygonal bar with the inner and outer radii between the two planes of intersection. The multi-faceted polygon provides a large surface to volume ratio for unique device applications.

FIG. 9G illustrates another embodiment of the structure that is a solid circular bar with the inner and outer radii 904 and 903 between the two planes of intersection 901 and 902. There are protrusions 907 distributed on the surface of the bar. The protrusions 907 may be grown from a bottom-up technology, for example, by nanowire growth.

FIG. 9H shows an SEM image of a bar with complex variation 908 in the cross-sectional area. This form of bar sculpting may be achieved by manipulating the process recipes for top-down etching (typically using DRIE) in combination with thermal oxidation.

FIG. 9I illustrates another embodiment of the structure that is a bar with complex non-linear variation in the cross-sectional area 908 on a mother substrate 103.

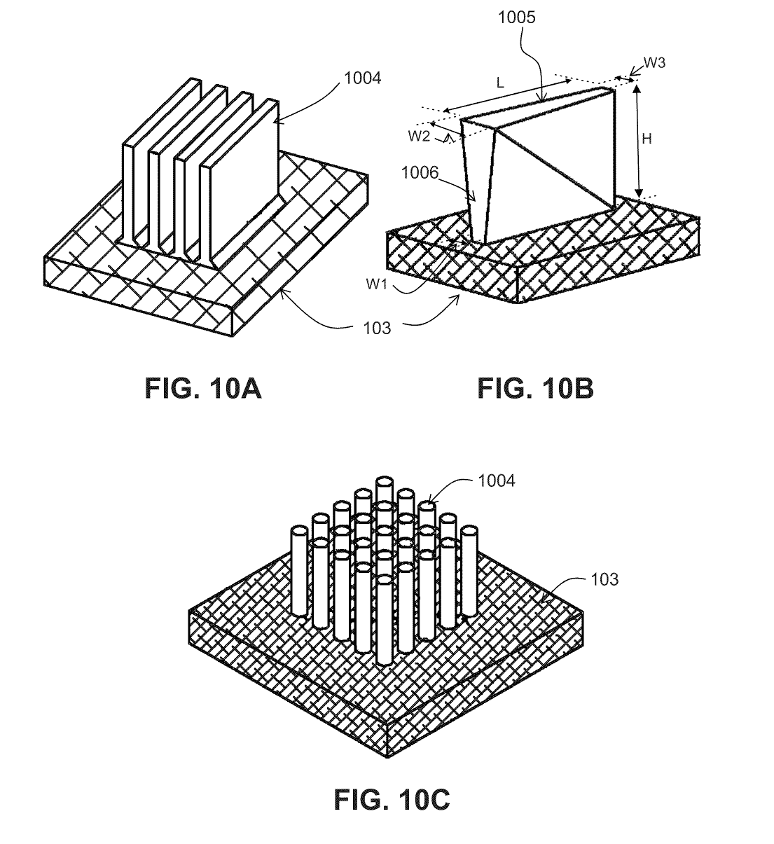

FIG. 10A illustrates another embodiment of the structure that is a thin wall 1004 on a mother substrate 103.

FIG. 10B illustrates another embodiment of the structure that is a complex thin wall 1004 with two orthogonal surfaces 1005 and 1006 with varying widths on a mother substrate 103.

FIG. 10C illustrates another embodiment of the structure that is an array of circular bars 1004 on a mother substrate 103.

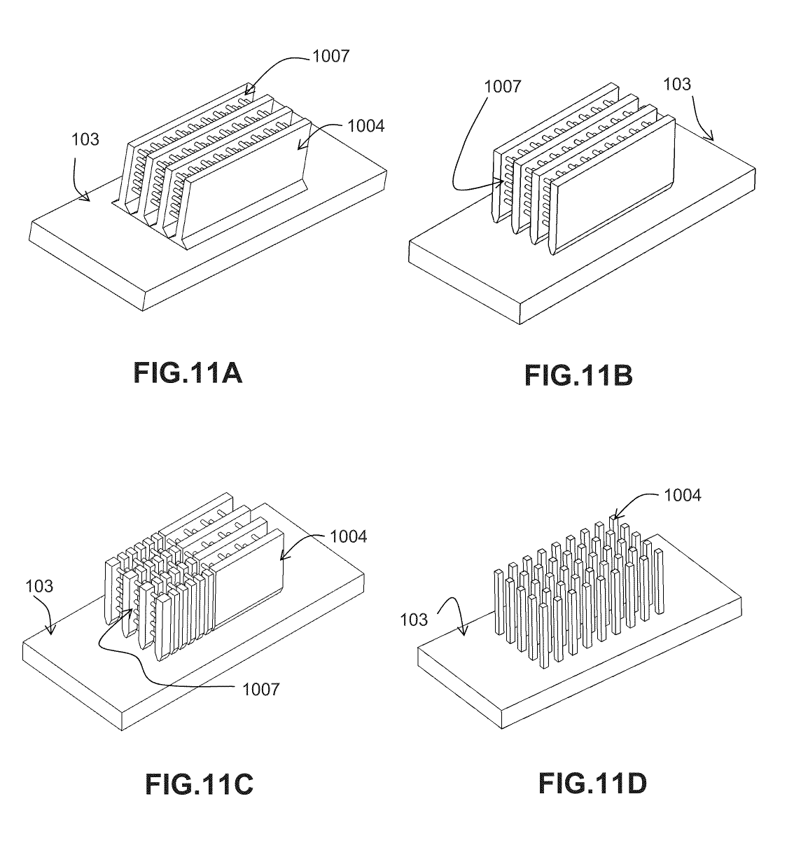

FIG. 11A illustrates another embodiment of the structure that is a thin wall 1004 on a mother substrate 103 with positive slopes at the base interconnected with protrusions 1007.

FIG. 11B illustrates another embodiment of the structure that is a thin wall 1004 on a mother substrate 103 with negative slopes at the base interconnected with protrusions 1007.

FIG. 11C illustrates another embodiment of the structure that is a thin wall 1004 on a mother substrate 103 with negative slopes at the base interconnected with protrusions 1007 and combined with free-standing bars.

FIG. 11D illustrates another embodiment of the structure that is an array of rectangular bars 1004 on a mother substrate 103 obtained in the limit that the thin walls are further etched in the orthogonal dimension to the longest width.

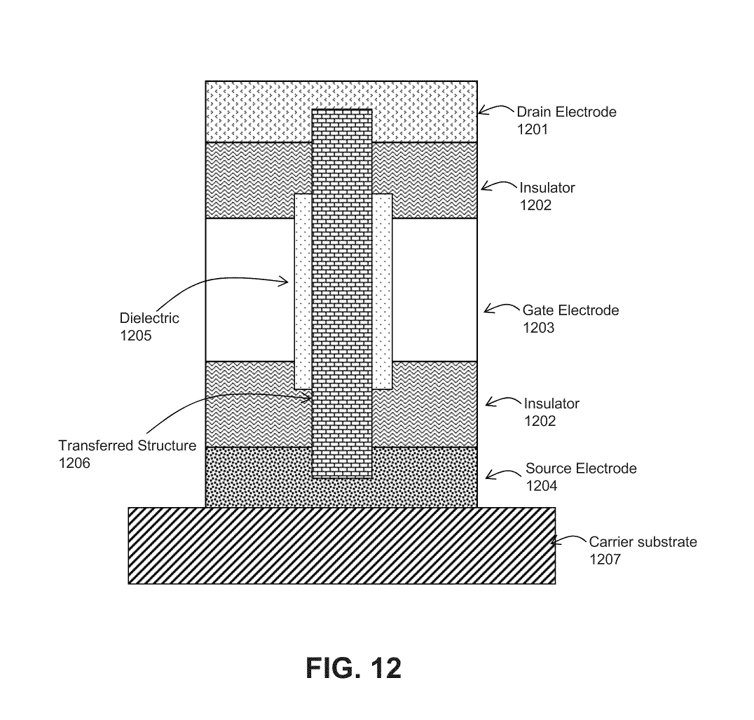

FIG. 12 illustrates another embodiment of the structure that is a bar 1206 associated with a dielectric annulus 1205 transferred onto a carrier substrate 1207 with a source electrode 1204, insulator 1202, gate electrode 1203, and a drain electrode 1201. The transferred structure 1206 forming the device may function as a transistor.

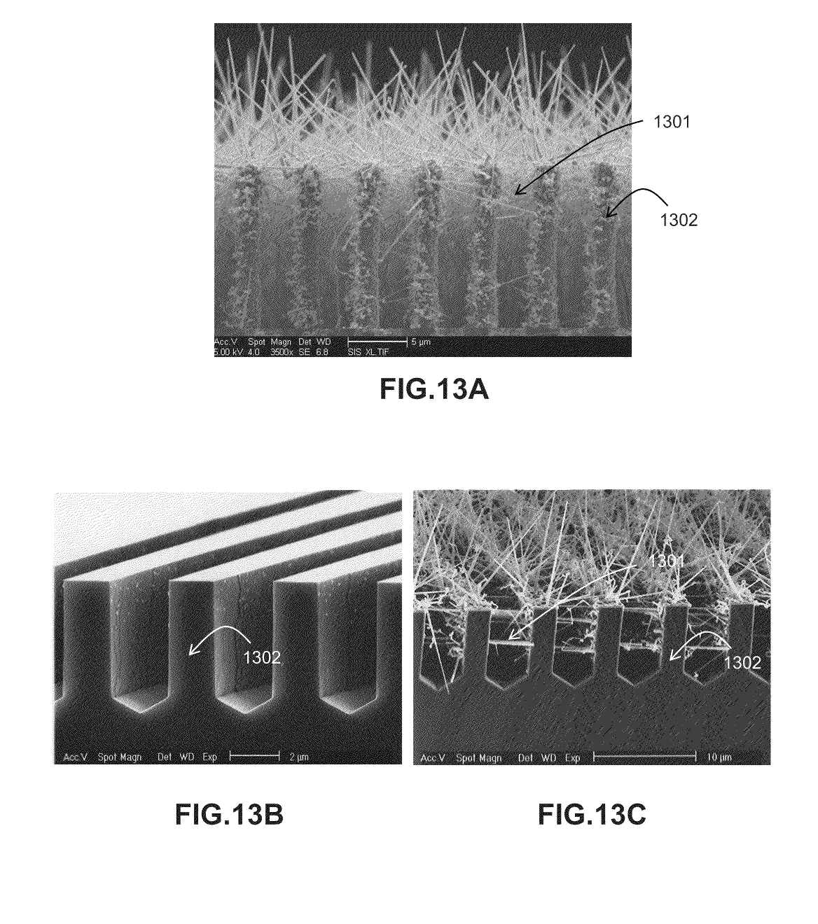

FIG. 13A shows an SEM image of one possible embodiment of the structure identified by protrusions 1301 and bars 1302 as illustrated in FIG. 9G or FIG. 11C. The protrusions in this instance are Silicon nanowires grown from chemical vapor deposition (CVD).

FIG. 13B shows an SEM image of one possible embodiment of the structure identified by thin walls 1302 as illustrated in FIGS. 11A to 11C while FIG. 13C shows protrusions 1301 interconnected between the thin walls 1302. The protrusions in this instance are Silicon nanowires grown from chemical vapor deposition (CVD).

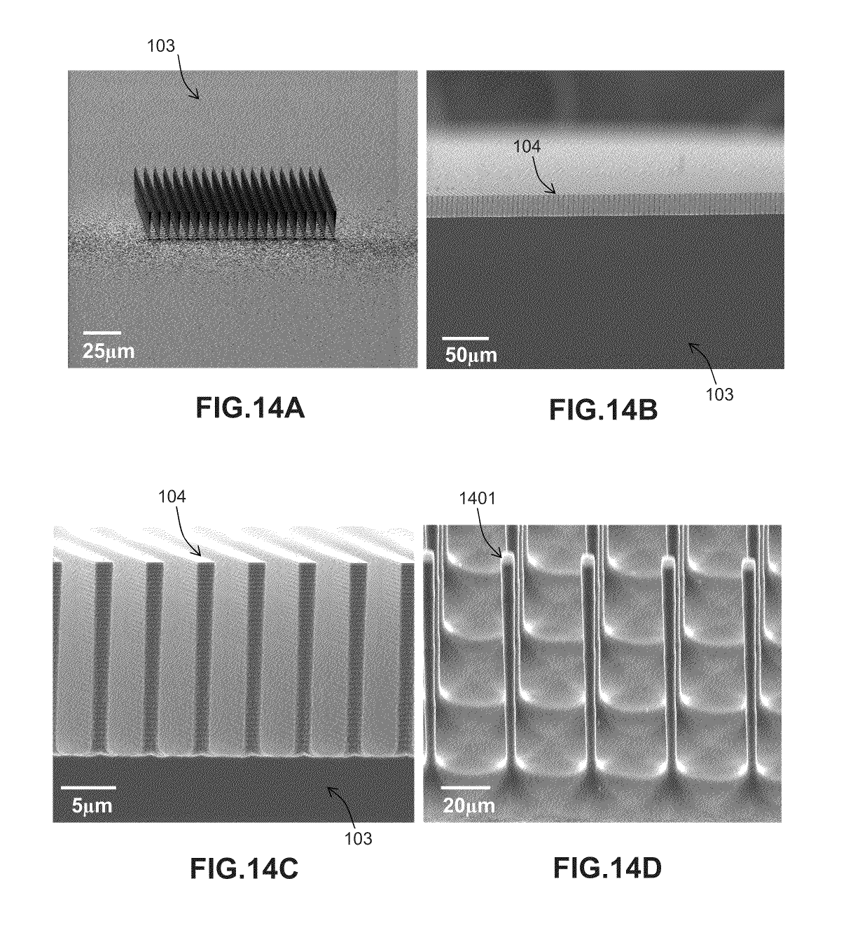

FIG. 14 illustrates images of high aspect ratio vertically oriented silicon micropillars fabricated using the deep reactive ion etching (DRIE) process based on the BOSCH recipe of cyclical passivation and etching. A highly doped p-type Si(100) substrate with doping concentration of ˜10¹⁹ cm⁻³ was patterned with 2 μm mask dots using a positive photoresist (Shipley S1813) that also acts as the etch mask for the subsequent DRIE process. The processing was done while keeping the substrate at 10° C. with SF₆ and C₄F₈ flow of 300 sccm and 150 sccm respectively, source RF power at 1800 W and substrate power at 20 W for a total etching time of ˜6 mins. The individual etching to passivation cycle ratio was 6:3 seconds and an O₂ 10 secs clean was executed before and after the process. The pressure of the chamber was regulated by holding the gate valve position at 42% for a nominal pressure of 0.1 mTorr. Two different patterns were etched: a 20×20 pillar array of dimensions ˜20 μm (height)×2 μm (diameter) and a uniformly patterned pillar array of dimensions ˜1.4 μm (diameter)×20 μm (height). The scalloping side-walls seen are a direct result of the DRIE process parameters in the etching-passivation BOSCH cycle. This surface imperfection can be smoothed by either optimizing the process or using thermal oxidation followed by a buffered oxide etch (BOE).

FIG. 14A presents an SEM image of one possible embodiment of the structure identified by circular bars on a mother substrate 103 as illustrated in FIG. 10C.

FIG. 14B presents an SEM image of one possible embodiment of the structure identified by rectangular bars 104 on a mother substrate 103 as illustrated in FIG. 11D.

FIG. 14C presents a close-up SEM image of one possible embodiment of the structure identified by rectangular bars 104 on a mother substrate 103 as illustrated in FIG. 11D.

FIG. 14D presents an SEM image of one possible embodiment of the structure identified by tapering bars 104 on a mother substrate 103 as illustrated partially in FIG. 9B.

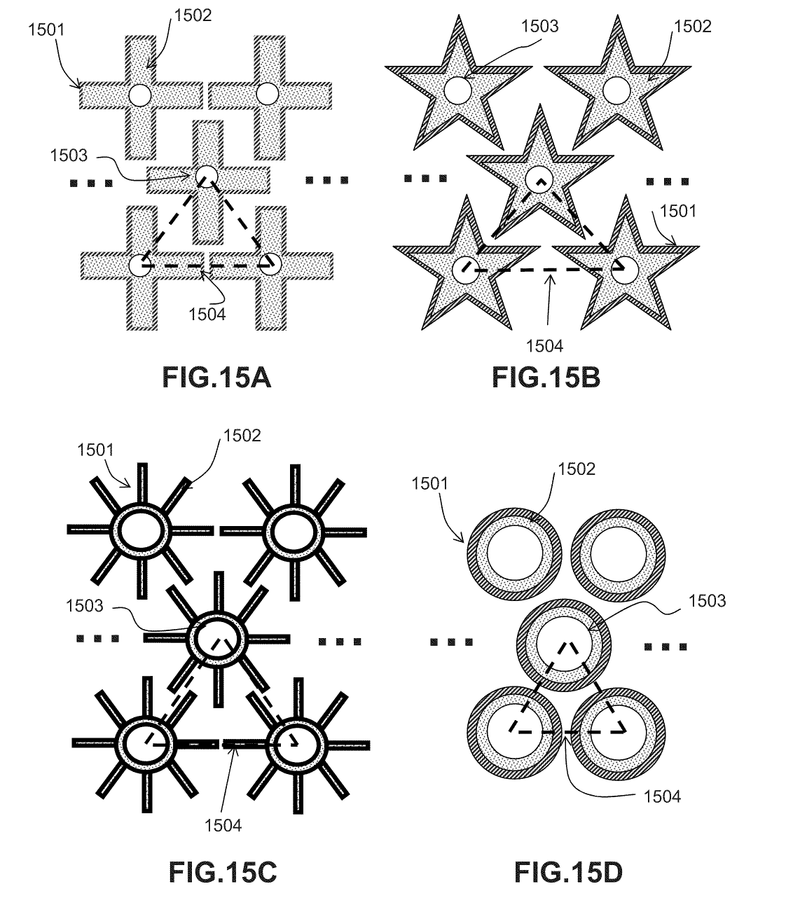

FIG. 15 illustrates various exemplary embodiments of the structure 104 commonly viewed from the orthogonally projected plane of intersection 901.

FIG. 15A to FIG. 15H specifically illustrate various embodiments of the structure with a cross-sectional area that has a “plus form,” “star form,” “fin form,” “circular form,” “blade form,” “rectangular form,” “hexagonal form,” and “rhomboid form,” among others with three distinct layers 1501, 1502 and 1503. These layers could be identified with differing physical and material properties, for example, variations in carrier concentrations, where 1501 could be a p-doped layer, 1502 an n-doped layer and 1503 a highly degenerate semiconductor core or a metal. The structures may further be arranged in a geometrical lattice 1504 to form an ordered array configuration.

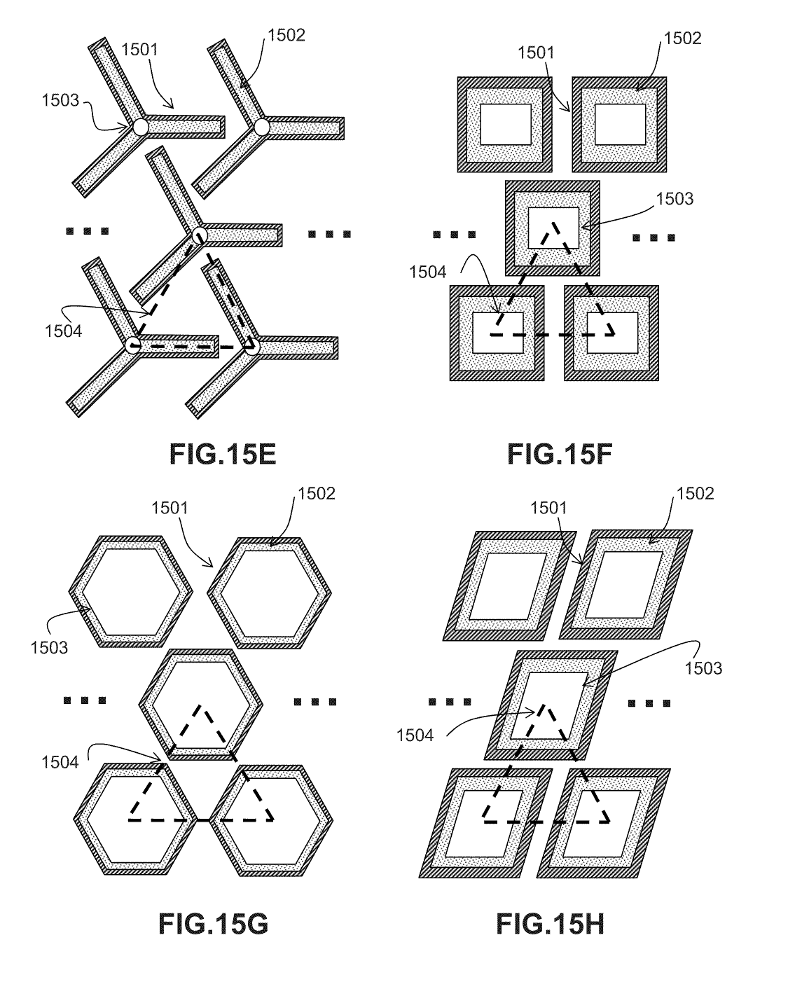

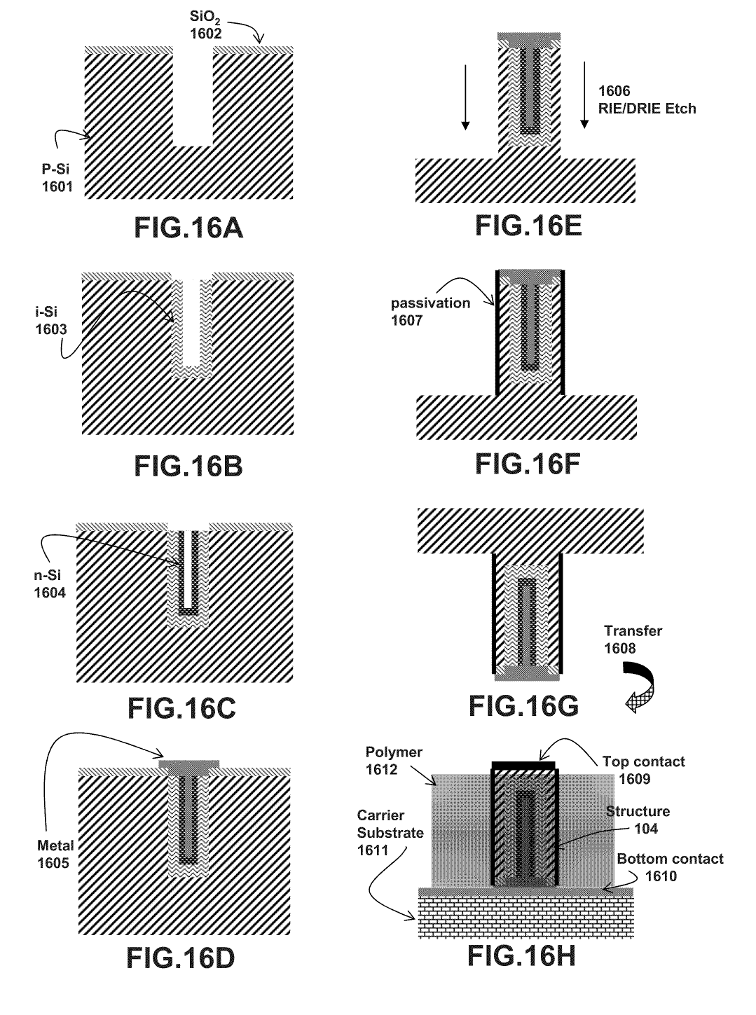

FIGS. 16A to 16H illustrate a mode of forming the structure 104, specifically a composite bar or pillar, using a top-down etching method with material deposition containing a p-i-n junction device in a core-shell configuration. Start with a p-doped Silicon mother substrate 1601 with a cavity via a SiO₂ mask 1602 and perform directional etching. Grow epitaxial intrinsic silicon 1603 followed by growing an n-doped Si layer 1604. Perform lithography to define an evaporation lift-off mask followed by metal deposition 1605. Re-pattern using photoresist and etch down 1606 the substrate protecting the structure 104 to define a bar or pillar. The passivation 1607 may be performed now by depositing, growing or spin-coating. Now the mother substrate is ready for transfer 1608. The mechanism has been disclosed in prior embodiments. Insulating polymer 1612, top electrical contact 1609, and bottom electrical contact 1610 may be deposited on the carrier substrate 1611.

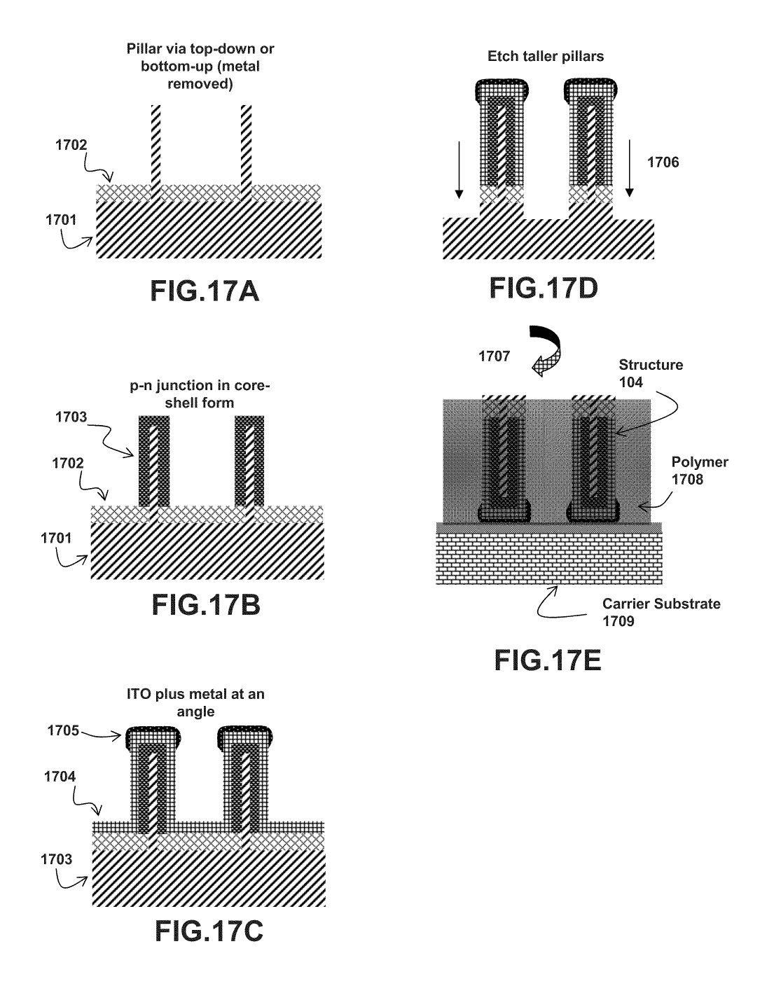

FIGS. 17A to 17E illustrate a mode of forming the structure, specifically a composite bar or pillar, using a bottom-up growth method or top-down etching method with material variation along the radial dimension forming a core-shell p-n junction device structure. Start with a p-doped Silicon mother substrate 1701 with patterned SiO₂ mask 1702 and grow p-doped nanowire or nanopillar from the bottom-up. Deposit or grow thin film n-doped Si layer 1703, followed by depositing ITO 1704 and metal angled deposition 1705. Re-pattern using photoresist and etch down 1706 the substrate protecting the structure 104 to define a bar or pillar. Now the mother substrate is ready for transfer 1707. The mechanism has been disclosed in prior embodiments. Insulating polymer 1708, top electrical contact, and bottom electrical contact may be deposited on the carrier substrate 1709.

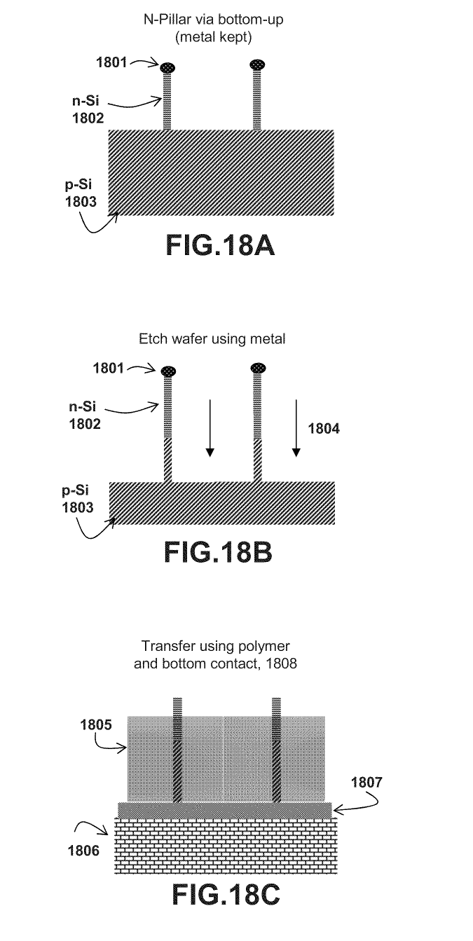

FIGS. 18A to 18C illustrate a mode of forming the structure, specifically a composite bar or pillar, using a bottom-up growth method with material variation along the axial dimension. Start with a p-doped Silicon mother substrate 1803 with patterned metal catalyst 1801 and grow n-doped nanowire or nanopillar from the bottom-up 1802. Re-pattern using photoresist and etch down 1804 the substrate protecting the structure 104 to define a bar or pillar with the catalyst in place. Now the mother substrate is ready for transfer 1808. The mechanism has been disclosed in prior embodiments. Insulating polymer 1805, top electrical contact, and bottom electrical contact may be deposited on the carrier substrate 1806.

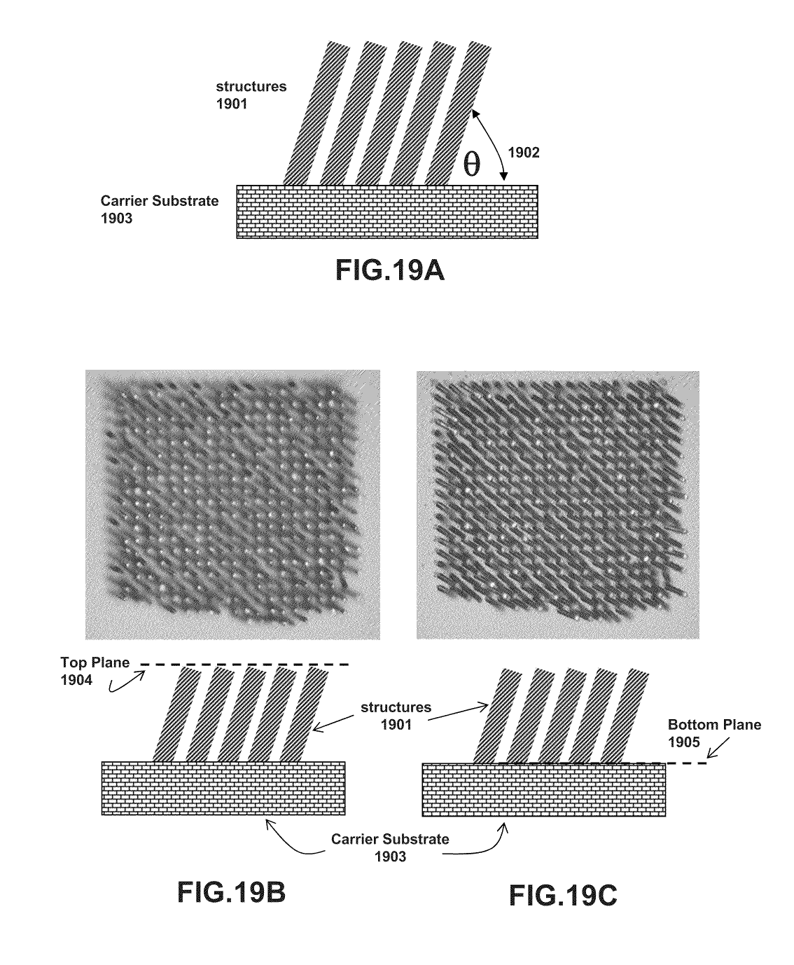

FIG. 19A illustrates a mode of controlling the angle of the structure 1901 defined by the angle 1902 extended between the major axis of the structure forming a composite bar or pillar and the carrier substrate 1903. The angle may be adjusted by obtaining a set of conditions optimized between the viscosity of the phase-change material, the vertical forces and the lateral fracture forces.

FIG. 19B shows an optical image of the angled structures, in this example, a 20 by 20 micropillar array on polymer KMPR focused at the top of the structures 1904.

FIG. 19C shows an optical image of the angled structures, in this example, a 20 by 20 micropillar array on polymer KMPR focused at the bottom of the structure 1905 and at the top of the carrier substrate.

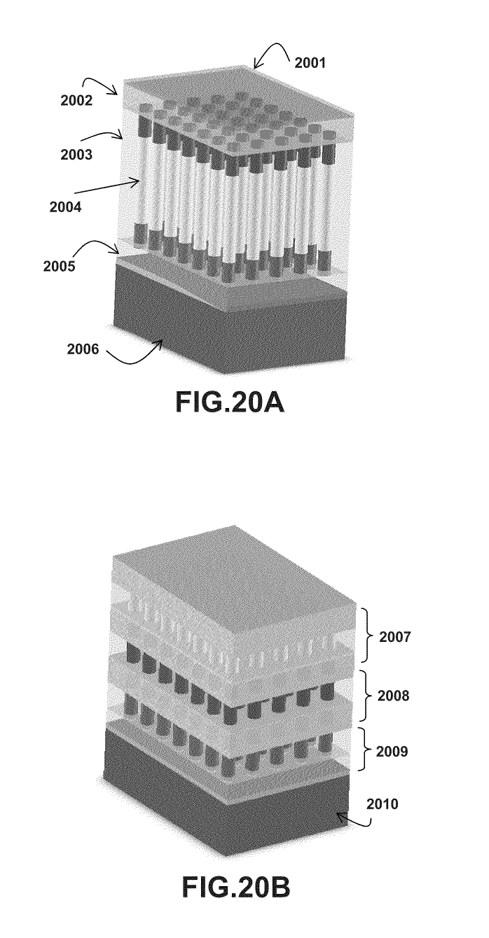

FIG. 20A illustrates a mode of forming an optoelectromechanical device, specifically a photovoltaic cell, from transferred structures 104 in accordance with one embodiment of the present invention. The device is formed using a P-I-N junction diode of nanowires 2004 tailored by axially varying the doping concentration. For example, based on a specific requirement for spectral absorption of a photovoltaic device or solar cell, a suitable mother substrate 103 is selected to grow the nanowire 2004. The mother substrate 103 is first chosen based on the type of nanowire desired to be grown (e.g Silicon, Germanium, GaN, GaAs, InP, GaP, among others) with the relevant doping species (p, i, n). Metal catalysts (e.g Au or Ti thin film or nanoparticles) are patterned or placed using various methods (e.g., lithography, sonification, soft contact printing) to define the location where the nanowire will be grown.

The mother substrate 103 is then placed in a CVD furnace and the nanowire is grown directionally using conventional techniques such as vapor-liquid-solid growth (VLS) to the specific height required (h_{structure}) 403. Different nanowire compositions may be grown, e.g., P-I-N or P-N. An n-type polymer (suitable dopant chosen) 2005 is separately spin-coated or dispensed on a cheaper carrier substrate 101 (e.g. plastic, glass). An insulating polymer (intrinsic) 2003 is subsequently spin-coated on top of the n-type polymer 2005. The polymers will have different glass transition temperatures (T_{g}) to better control the interlayer adhesion as well as to permit independent layer liquification prior to nanowire embedment. The mother substrate 103 is now aligned with the carrier substrate 101. Upon alignment, the top mother substrate 103 containing the directionally grown nanowire (also acting as the mold) is embossed into the heated carrier substrate 101 that softens the i-polymer (T_{g1}) 2003 without affecting the n-polymer (T_{g2}) 2005, where T_{g1} is lower than T_{g2}. After the completion of the embossing step, the mother substrate 103 and carrier substrate 101 are sheared via mechanical force (or other technique such as high-speed water jet) to cutoff the nanowire 2004 base from mother substrate 103. The exposed nanowire base is now cleaned chemically to ensure that during the spin-coating of the p-polymer 2002, the established contacts are of good quality. A top electrode layer 2001 is now deposited to contact the p-polymer 2002. The expensive substrate can now be re-used to re-grow new nanowires. The process steps are cyclical.

FIG. 20B illustrates a mode of forming an optoelectromechanical device, specifically a solar cell, using the transferred structures 104 by stacking multiple individual devices in tandem that absorbs at different electromagnetic spectra from (γₐ to γ_{b}) 2007, (γ_{c} to γ_{d}) 2008 and (γₑ to γ_{f}) 2009 on a carrier substrate 2010 to increase the solar cell efficiency. The range of wavelengths (γₐ to γ_{b}) 2007, (γ_{c} to γ_{d}) 2008 and (γₑ to γ_{f}) 2009 may overlap with varying or similar magnitude in the photoresponse.

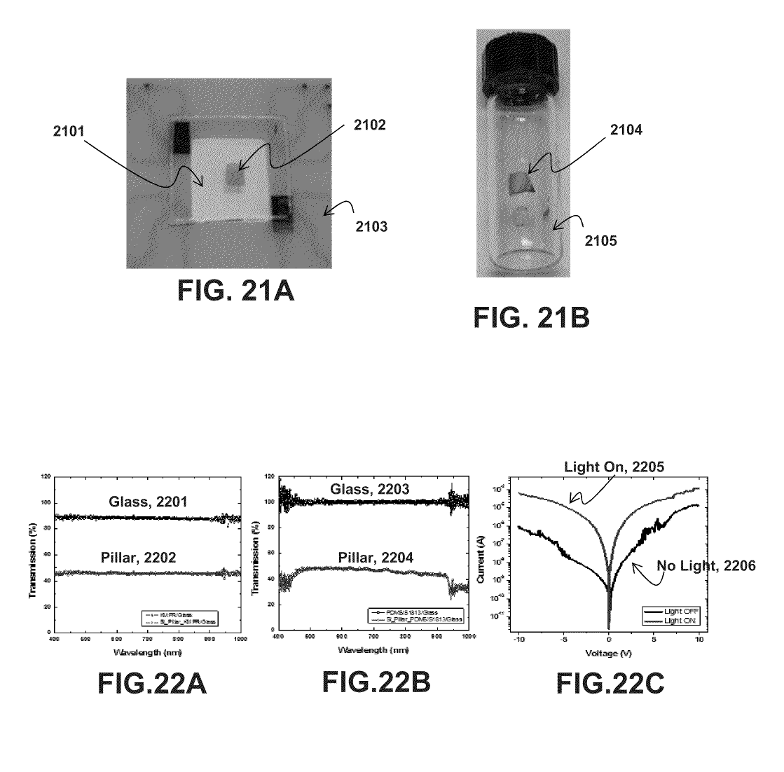

FIG. 21A presents an optical image of the device with an array of transferred vertically ordered structures 2102 on PDMS-coated glass 2101 mounted on an insulating material 2103 in accordance with one embodiment of the present invention.

FIG. 21B presents an optical image of the device with an array of transferred vertically ordered structures 2104 on curved glass surface 2105 in accordance with one embodiment of the present invention.

FIG. 22A presents the optical transmission properties of the transferred structures 104, in this instance, micropillars on KMPR 2201 and the corresponding reference on glass 2202, in accordance with one embodiment of the present invention. The reduction in transmission magnitude over the range of measured wavelength shows significant absorption by the transferred micropillars.

FIG. 22B presents the transmission properties of the transferred structures 104, in this instance, micropillars on PDMS, in accordance with one embodiment of the present invention. The absorption from the micropillars is evident in the reduction of the magnitude of optical transmission 2204 compared to the reference on glass 2203.

FIG. 22C presents the electrical properties of the transferred structures 104, in this instance micropillars on KMPR, with 2205 and without optical illumination 2206 in accordance with one embodiment of the present invention.

### CONCLUSION

Embodiments of the present invention provide techniques for transferring an ordered array of 3D micro/nanostructures from a mother substrate to a carrier substrate. After the structure transfer, the vertical orientations of the structures are preserved (i.e., direct 3D-to-3D) while the volume density of the final device may be increased. Generally, any starting mother substrates or carrier substrates (such as SOI) can be used, and the transfer process can be performed under ambient and/or low temperature processes (<250° C.). The choice of the transfer polymers can include, but is not limited to, polydimethylsiloxane (PDMS), polymethylmetacrylate (PMMA), polyimide, KMPR or SU-8.

The foregoing descriptions of embodiments of the present inventions have been presented only for purposes of illustration and description. They are not intended to be exhaustive or to limit the present invention to the forms disclosed. Accordingly, many modifications and variations will be apparent to practitioners skilled in the art. Additionally, the above disclosure is not intended to limit the present invention. The scope of the present invention is defined by the appended claims.

What is claimed is:

1. A method for fabricating multiple devices on a single substrate based on a structure transfer process, the method comprising:
forming structures of multiple devices on a first substrate;
bonding the structures of the multiple devices onto a second substrate; and
transferring the multiple devices from the first substrate onto the second substrate by fracturing the structures of the multiple devices off the first substrate, wherein the transferred devices preserve physical orientation and material properties of the said fabricated structures.

2. The method of claim 1, wherein prior to bonding the structures of the multiple devices onto the second substrate, the method further comprises:
forming a phase-change material coating on the second substrate; and
aligning the first substrate with the second substrate so that the structures on the first substrate are aligned over the phase-change material coating on the second substrate.

3. The method of claim 2, wherein bonding the structures of the multiple devices onto the second substrate involves:
pressing the second substrate against the first substrate so that at least a portion of the structures on the first substrate is imprinted and embedded into the phase-change material coating on the second substrate; and
hardening the phase-change material coating so that the embedded portion of the structures on the first substrate is bonded with the phase-change material coating and forms anchors for the first substrate on the second substrate.

4. The method of claim 3, wherein prior to and during pressing the second substrate against the first substrate, the method further involves softening the phase-change material coating to reduce the viscosity of the phase-change material coating.

5. The method of claim 4,
wherein softening the phase-change material coating involves heating the phase-change material coating; and
wherein hardening the phase-change material coating involves cooling the phase-change material coating or treating the phase-change material coating with electromagnetic radiation.

6. The method of claim 2, wherein bonding the structures of the multiple devices onto the second substrate involves:
softening the phase-change material coating to reduce the viscosity of the phase-change material coating; and
pressing the second substrate against the first substrate so that at least a portion of the structures on the first substrate is imprinted and embedded into the phase-change material coating on the second substrate,
wherein the embedded portion of the structures on the first substrate is bonded with the phase-change material coating and forms anchors for the first substrate on the second substrate.

7. The method of claim 6, wherein softening the phase-change material coating can include:
heating the phase-change material coating; or
treating the phase-change material coating with an electromagnetic radiation.

8. The method of claim 1, wherein fracturing the structures of the multiple devices off the first substrate involves causing a relative motion between the first substrate and the second substrate, wherein the relative motion causes a stress-strain induced mechanical failure of the structures in the vicinity where the structures join the first substrate.

9. The method of claim 8, wherein causing the relative motion between the first substrate and the second substrate involves applying a force or displacement on the bonded structure of the first substrate and the second substrate.

10. The method of claim 9, wherein the force can be applied to:
the first substrate only;
the second substrate only; or
both substrates.

11. The method of claim 9, wherein the force can be:
a translational force;
a rotational force; or
a combination of the above.

12. (canceled)

13. The method of claim 2, wherein after transferring the multiple devices from the first substrate onto the second substrate, the method further comprises:
depositing a filling material layer on the phase-change material coating and the transferred structures of the multiple devices, wherein the top surface of the filling material layer is below the top of the transferred structures; and
depositing a capping layer over the filling material layer and the transferred structures, thereby encapsulating the transferred structures of the multiple devices.

14. The method of claim 13, wherein the filling material layer is an insulation layer.

15. The method of claim 13, wherein the capping layer is a conductive layer.

16. (canceled)

17. (canceled)

18. (canceled)

19. (canceled)

20. (canceled)

21. The method of claim 1, wherein the orientation angle of the transferred structures on the second substrate can vary between 0 degrees to 90 degrees with respect to the surface of the second substrate.

22. The method of claim 2, wherein the phase-change material coating can be a metal-organic composite coating or a polymer coating, wherein the polymer can include thermoplastics, such as polymethylmethacrylate (PMMA), polycarbonate, polyethylene, polystyrenes, polyamide, and thermosetting plastics.

23. The method of claim 1, wherein the structures can include pillars of a height of at least 500 nm, and a cross-sectional dimension varying from 10 nm to 100 μm, wherein the structures are formed on a surface parallel to the first substrate.

24. The method of claim 1, wherein the structures can include thin walls of length L, which is at least 500 nm long, and width W, which is between 10 nm to 100 μm, wherein the thin walls are formed on a surface parallel to the first substrate.

25. The method of claim 1, wherein the structures can include columns with comparable dimensions between the walls length, L and widths, W1, W2, and W3.

26. The method of claim 1, wherein the method is repeated to form a vertical integrated stack of structures of the multiple devices on the second substrate.

27. The method of claim 1, wherein the structures is covered by protrusions at any arbitrary crystal orientation for either mechanical support and/or additional electrical junctions, wherein the protrusions is formed by controlling the catalyst thickness, the growth temperature, gas flow and pressure.

28. The method of claim 1, wherein the structures is covered by a patterned layer functioning as a mask and/or as a charge transport layer.

29. The method of claim 1, wherein the cross-section of the structures can include:
pentagon;
hexagonal;
octagon;
circular;
square;
rectangular; or
any other polygon shape.

30. The method of claim 1, wherein the structures have a central core of varying cross-sections and connected by sub-structures of blades, and fins.

31. The method of claim 1, wherein one or more layers in the structures are photon reflecting layers.

32. The method of claim 1, wherein the structures have thin walls of length, L varying from 500 nm to any conventional wafer size, the width, W1 and W2, varying from 10 nm to 100 μm formed on a surface orthogonal to the substrate,
wherein the width, W1 or W2 may or may not be equal;
wherein the height, H1 may vary between 100 nm to a conventional wafer thickness; and
wherein the walls are formed by transformative top down and/or synthetic bottom up approach.

33. The method of claim 1, wherein the structures are oriented by oscillation or vibration.

34. The method of claim 1, wherein the structures are hollow, annular, and have different cross-sections.

35. The method of claim 1, wherein the second substrate is capable of supporting a polymer or epoxy suitable for the extraction of the nanowires and the capability to withstand the subsequent processing conditions.

36. (canceled)

37. The method of claim 2, wherein the phase-change material coating can include a charge transport layer.

38. The method of claim 2, wherein the phase-change material coating is a multilayer of one or more charge transport layers, which can include a thermoplastic, thermosetting resin, and polymeric sheet layer(s).

39. The method of claim 1, wherein the second substrate is coated with a polymer or an epoxy layer which is subsequently cured or allowed to cure.

40. The method of claim 39, wherein the polymer or epoxy layer is selectively cured, such as by applying heat to only the second substrate to facilitate structure transfer.

41. The method of claim 39, wherein the polymer layer is selectively cured laterally and/or vertically by controlling the focus and/or intensity of electromagnetic radiation to facilitate nanowire transfer.

42. The method of claim 39, wherein the epoxy resin and curing agent with a chemically-reactive excess of resin (or curing agent) is applied to the second substrate (or the original substrate) and only the curing agent (or epoxy) is applied to the original nanowire (or transfer) substrate to facilitate nanowire transfer.

43. The method of claim 1, wherein the structures are angularly tilted via UV curing, transfer control for directed photon trapping.

44. (canceled)

45. (canceled)

46. The method of claim 1, wherein the multiple devices include optoelectronic/photovoltaic solar cells which are formed by growing nanowire or etching pillars on the first substrate.

47. The method of claim 46, wherein growing the nanowire involves patterning a metal catalyst on the first substrate to define locations where the nanowires are grown.

48. The method of claim 46, wherein the structures for the photovoltaic solar cell can be comprised of Silicon, Galium Nitride (GaN), Indium Phosphide (InP), Galium Phosphide (GaP) and/or Germanium (Ge).

49. The method of claim 46, wherein the photovoltaic solar cell can be:
a nanowire embedded P-I-N solar cell; or
a nanowire embedded P-N solar cell.

50. (canceled)

51. (canceled)

52. The method of claim 1, wherein the first substrate can include:
a GaAs substrate;
a GaP substrate;
a Ge substrate;
a Si substrate; or
any other common substrate for multiple device fabrication.

53. The method of claim 2, wherein the second substrate can be made of:
plastic;
glass;
textile; or
any material that supports or can be surface-treated to support the phase-change material layer.

54. The method of claim 2, wherein the phase-change material can be:
an electrically conductive material;
a non-conductive/conductive polymer blend; or
a conducting particle/polymer composite.

55. A solar power generation cell produced by:
fabricating structures for the solar cell on a first substrate; and
transferring the structures from the first substrate to a second substrate.

56. The solar power generation cell of claim 55, where the structures can include a core-shell P-N or P-I-N junction,
wherein the core can be a charge transport material;
wherein the core-shell can be formed via a combination of bottom-up and top-down processes; and
wherein the charge transport core can be formed by one of: spin-coating, dip-coating, evaporation, and sputtering.
